(19) United States
(12) Patent Application Publication
(10) Pub. No.: US 2023/0352409 A1
(43) Pub. Date: Nov. 2, 2023

(54) INTERCONNECT STRUCTURE INCLUDING SINGLE LAYER SERVING AS BOTH BARRIER LAYER AND LINER LAYER

(71) Applicant: TAIWAN SEMICONDUCTOR MANUFACTURING COMPANY, LTD., Hsinchu (TW)

(72) Inventors: Meng-Pei LU, Hsinchu (TW); Shin-Yi YANG, Hsinchu (TW); Ching-Fu YEH, Hsinchu (TW); Chin-Lung CHUNG, Hsinchu (TW); Cian-Yu CHEN, Hsinchu (TW); Yun-Chi CHIANG, Hsinchu (TW); Tsu-Chun KUO, Hsinchu (TW); Ming-Han LEE, Hsinchu (TW)

(73) Assignee: TAIWAN SEMICONDUCTOR MANUFACTURING COMPANY, LTD., Hsinchu (TW)

(21) Appl. No.: 17/730,453

(22) Filed: Apr. 27, 2022

(51) Int. Cl. H01L 23/532; H01L 21/768; H01L 23/522

(52) U.S. Cl. CPC H01L 23/53238; H01L 23/53266; H01L 23/53252; H01L 23/53223; H01L 21/76877; H01L 23/5226; H01L 21/76831; H01L 21/76846

(57) ABSTRACT

A semiconductor device includes a substrate and an interconnect layer disposed on the substrate. The interconnect layer includes a dielectric layer and an interconnect extending through the dielectric layer. The interconnect includes a bulk metal region and a single barrier/liner layer, which serves as both a barrier layer and a liner layer and which is disposed to separate the bulk metal region from the dielectric layer.

### BACKGROUND

An interconnect structure with a single or dual damascene architecture is usually formed in a middle end of line (MEOL) process and/or a back end of line (BEOL) process by sequentially and separately depositing a barrier layer and a liner layer, followed by filling a metal material (e.g., cupper (Cu)) into an opening defined by the liner layer. The barrier layer is made of metal nitride, and is used for preventing the metal material from diffusing into neighboring sensitive regions. Copper diffusion may negatively affect performance of a semiconductor device, or may even lead to complete failure of the semiconductor device. The liner layer is made of a single metal, and is used for permitting the metal material to be deposited thereon.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor device in accordance with some embodiments.

FIGS. 2 to 7 are schematic views illustrating some intermediate stages of the manufacturing method as depicted in FIG. 1 in accordance with some embodiments.

FIGS. 8 to 12 are each a schematic view illustrating a semiconductor device in accordance with some alternative embodiments.

FIG. 13 is a flow diagram illustrating a method for manufacturing a semiconductor device in accordance with some embodiments.

FIGS. 14 to 21 are schematic views illustrating some intermediate stages of the manufacturing method as depicted in FIG. 13 in accordance with some embodiments.

FIG. 22 is a flow diagram illustrating a method for manufacturing a semiconductor device in accordance with some embodiments.

FIGS. 23 to 31 are schematic views illustrating some intermediate stages of the manufacturing method as depicted in FIG. 22 in accordance with some embodiments.

FIGS. 32 to 37 are each a schematic view illustrating a semiconductor device in accordance with some alternative embodiments.

FIG. 38 is a flow diagram illustrating a method for manufacturing a semiconductor device in accordance with some embodiments.

FIGS. 39 to 46 are schematic views illustrating some intermediate stages of the manufacturing method as depicted in FIG. 38 in accordance with some embodiments.

FIG. 47 is a flow diagram illustrating a method for manufacturing a semiconductor device in accordance with some embodiments.

FIGS. 48 to 55 are schematic views illustrating some intermediate stages of the manufacturing method as depicted in FIG. 47 in accordance with some embodiments.

FIG. 56 is a flow diagram illustrating a method for manufacturing a semiconductor device in accordance with some embodiments.

FIGS. 57 to 62 are schematic views illustrating some intermediate stages of the manufacturing method as depicted in FIG. 56 in accordance with some embodiments.

FIGS. 63 to 67 are each a schematic view illustrating a semiconductor device in accordance with some alternative embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “over,” “below,” “upper,” “lower,” “downwardly,” “upwardly,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

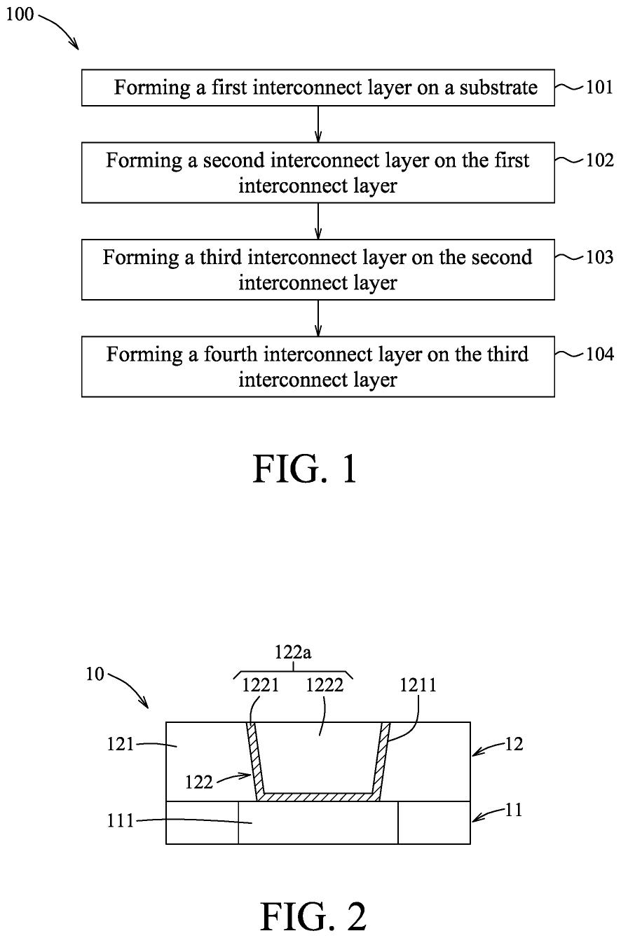

The present disclosure is directed to a semiconductor device including at least one interconnect layer formed with an interconnect which includes a single layer serving as both a barrier layer and a liner layer, and a method for manufacturing the same. FIG. 1 illustrates a method 100 for manufacturing a semiconductor device in accordance with some embodiments. FIGS. 2 to 7 are schematic views of a semiconductor device 10 at some intermediate stages of the manufacturing method as depicted in FIG. 1 in accordance with some embodiments. Additional steps can be provided before, after or during the method 100, and some of the steps described herein may be replaced by other steps or be eliminated. Similarly, further additional features may be present in the semiconductor device 10, and/or features present may be replaced or eliminated in additional embodiments.

Referring to FIG. 1 and the example illustrated in FIG. 2, the method 100 begins at step 101, where a first interconnect layer is formed on a substrate. FIG. 2 is a schematic view illustrating formation of a first interconnect layer 12 on a substrate 11.

In some embodiments, the substrate 11 is a semiconductor substrate which may include, for example, but not limited to, an elemental semiconductor or a compound semiconductor. An elemental semiconductor includes a single species of atoms, such as silicon (Si) or germanium (Ge) in column XIV of the periodic table, and may be in crystal, polycrystalline, or an amorphous form. Other suitable materials are within the contemplated scope of the present disclosure. A compound semiconductor includes two or more elements, and examples thereof may include, but not limited to, silicon carbide (SiC), gallium arsenide (GaAs), gallium phosphide (GaP), indium phosphide (InP), indium arsenide (InAs), indium antimonide (InSb), silicon germanium (SiGe), gallium arsenide phosphide (GaAsP), aluminum indium arsenide (AlInAs), aluminum gallium arsenide (AlGaAs), gallium indium arsenide (GaInAs), gallium indium phosphide (GaInP), and gallium indium arsenide phosphide (GaInAsP). Other suitable materials are within the contemplated scope of the present disclosure. The compound semiconductor may have a gradient feature in which the compositional ratio thereof changes from one location to another location therein. The compound semiconductor may be formed over a silicon substrate. The compound semiconductor may be strained. In some embodiments, the semiconductor substrate may include a multilayer compound semiconductor structure. In some embodiments, the semiconductor substrate may be a semiconductor on insulator (SOI) (e.g., silicon germanium on insulator (SGOI)). Generally, an SOI substrate includes a layer of a semiconductor material such as epitaxial silicon, germanium, silicon germanium, or combinations thereof. Other suitable materials are within the contemplated scope of the present disclosure. The SOI substrate may be doped with a P-type dopant, for example, but not limited to, boron (Br), aluminum (Al), or gallium (Ga). Other suitable materials are within the contemplated scope of the present disclosure. Alternatively, the SOI substrate may be doped with an N-type dopant, for example, but not limited to, nitrogen (N), phosphorus (P), or arsenic (As). Other suitable materials are within the contemplated scope of the present disclosure. In some embodiments, the semiconductor substrate may further include various active regions, for example, the active regions configured for an N-type metal oxide semiconductor transistor device (NMOS) or the active regions configured for a P-type metal oxide semiconductor transistor device (PMOS). A source/drain (S/D) region 111 of a transistor device is illustrated as the active region.

In some embodiments, the first interconnect layer 12 is formed on the substrate 11, and includes an inter-layer dielectric (ILD) layer 121 and an interconnect structure 122 formed in the ILD layer 121. The ILD layer 121 may include dielectric materials, such as silicon oxide (SiOx), silicon nitride (SiNx), silicon carbide (SiCx), silicon oxycarbide (SiOxCy), silicon oxynitride (SiOxNy), hydrogenated silicon oxycarbide (SiOxCyHz), spin-on glass (SOG), amorphous fluorinated carbon, fluorinated silica glass (FSG), Xerogel, Aerogel, polyimide, Parylene, BCB (bis-benzocyclobutenes), Flare, SiLK (Dow Chemical Co., Midland, Mich.), non-porous materials, porous materials, other low-k dielectric materials, or combinations thereof. Other suitable materials are within the contemplated scope of the present disclosure. In some embodiments, the ILD layer 121 may have a k-value ranging from about 1 to about 5. The interconnect structure 122 includes an interconnect 122a, which includes a bulk metal region 1222 and a single layer 1221 serving as both a barrier layer and a liner layer (referred to as a single barrier/liner layer hereinafter). The single barrier/liner layer 1221 is disposed to separate the bulk metal region 1222 from the ILD layer 121. In some embodiments, the interconnect 122a serves as a conductive contact disposed on the S/D region 111 in the substrate 11. The interconnect structure 122 is formed in the MEOL process.

In some embodiments, the first interconnect layer 12 may be formed using a single damascene process. The ILD layer 121 is deposited on the substrate 11 by a suitable deposition process as is known in the art of semiconductor fabrication, such as physical vapor deposition (PVD), chemical vapor deposition (CVD), atomic layer deposition (ALD), plasma-enhanced ALD (PEALD), thermal ALD, plasma-enhanced CVD (PECVD), or the like. Other suitable techniques are within the contemplated scope of the present disclosure. A mask layer (for example, a hard mask layer, not shown) is deposited on the ILD layer 121. The mask layer may include, for example, but not limited to, silicon oxide, silicon nitride, silicon carbide, silicon oxycarbide, silicon oxynitride, silicon carbonitride, silicon oxycarbonitride, tungsten nitride, tungsten carbide, titanium nitride, zirconium oxide, aluminum oxide, yttrium oxide, aluminum oxynitride, hafnium oxide, hafnium zirconium oxide, hafnium silicon oxide, hafnium silicon oxynitride, zirconium silicon oxide, hafnium zirconium silicon oxide, hafnium aluminum oxide, hafnium aluminum nitride, zirconium aluminum oxide, ytterbium oxide, or combinations thereof. Other suitable materials are within the contemplated scope of the present disclosure. The mask layer may be formed on the ILD layer 121 by a suitable deposition process as is known in the art of semiconductor fabrication, such PVD, CVD, ALD, PEALD, thermal ALD, PECVD, or the like. Other suitable techniques are within the contemplated scope of the present disclosure. A photoresist layer (not shown) is then formed on the mask layer by a suitable fabrication technique known to those skilled in the art of semiconductor fabrication, for example, but not limited to, a spin-on technique. Other suitable techniques are within the contemplated scope of the present disclosure. The photoresist layer is then patterned using a suitable photolithography technique to form an opening pattern. For example, the photoresist layer is exposed to light for patterning, followed by developing to form the opening pattern. The opening pattern formed in the photoresist layer is transferred to the mask layer using an etching processes, for example, but not limited to, a wet etching process, a dry etching process, a reactive ion etching process, a neutral beam etching process, or the like. After the opening pattern is transferred to the mask layer, the photoresist layer may be removed by, for example, but not limited to, an ashing process. The opening pattern formed in the mask layer is then transferred to the ILD layer 121 using a suitable etching process, for example, but not limited to, a wet etching process, a dry etching process, or the like, so as to form a recess (an opening) 1211 extending through the ILD layer 121 to expose the S/R region 111 therethrough. Other suitable etching techniques are within the contemplated scope of the present disclosure.

The single barrier/liner layer 1221 is formed in the opening 1211 by conformally depositing a single layer including a main component and a doping component on the ILD layer 121 using a suitable deposition process as is known in the art of semiconductor fabrication, such as PVD, CVD, ALD, PEALD, thermal ALD, PECVD, or the like, and then removing excess of the single layer over the ILD layer 121 by a planarization process (for example, but not limited to, a chemical mechanical planarization (CMP) process, an etching back process, or the like). In some embodiments, the main component includes a liner metal, which may include, for example, but not limited to, cobalt (Co), ruthenium (Ru), tantalum (Ta), or the like, suitable for forming a metal liner layer, or combinations thereof. Other suitable metal materials are within the contemplated scope of the present disclosure. In some embodiments, the doping component includes a barrier metal, which may include, for example, but not limited to, tantalum (Ta), zinc (Zn), manganese (Mn), zirconium (Zr), titanium (Ti), hafnium (Hf), niobium (Nb), vanadium (V), chromium (Cr), scandium (Sc), yttrium (Y), silicon (Si), tungsten (W), molybdenum (Mo), aluminum (Al), or the like, suitable for forming a metal barrier layer, or combinations thereof. Other suitable metal materials are within the contemplated scope of the present disclosure. The main component and the doping component are different from each other.

In some embodiments in which CVD is used for forming the single barrier/liner layer 1221, a first precursor including the main component and a second precursor including the doping component are processed by CVD in a chamber. In some embodiments in which PVD is used for forming the single barrier/liner layer 1221, a first target including the main component and a second target including the doping component are processed by PVD in a chamber. Alternatively, an alloy target including both the main component and the doping component may be processed by PVD in a chamber. In some embodiments, the deposition process for forming the single barrier/liner layer 1221 may be performed at a temperature ranging from about 25° C. to about 400° C. If the temperature of the deposition process is higher than 400° C., the materials and the features disposed proximate to the single barrier/liner layer 1221 may be damaged.

In some embodiments, the single barrier/liner layer 1221 has a thickness ranging from about 5 angstrom (A) to about 50 Å. If the thickness is less than 5 Å, the single barrier/liner layer 1221 may not be configured as a continuous layer. If the thickness is greater than 50 Å, the remaining volume of the opening 1211 for filling a metal material to form the bulk metal region 1222 is undesirably decreased, resulting in an increase in the resistance of the interconnect structure 122 thus formed.

A metal material is then filled into the remaining volume of the opening 1211 by reflowing, direct plating (for example, but not limited to, electro-chemical plating (ECP)), a suitable deposition process as is known to those skilled in the art of semiconductor fabrication (for example, but not limited to, selective or non-selective PVD, selective or non-selective CVD, selective or non-selective PECVD, selective or non-selective ALD, selective or non-selective PEALD, electroless deposition (ELD)), or the like, and a planarization process (e.g., CMP) is then performed to remove excess of the metal material over the ILD layer 121 so as to form the bulk metal region 1222.

In some embodiments, the metal material for forming the bulk metal region 1222 may include, for example, but not limited to, metals (e.g., copper (Cu), silver (Ag), gold (Au), Al, nickel (Ni), Co, ruthenium (Ru), iridium (Ir), platinum (Pt), palladium (Pd), osmium (Os), W, Mo, Ta, or the like), alloys thereof possessing promising conductive properties, or the like. Other suitable metal materials are within the contemplated scope of the present disclosure.

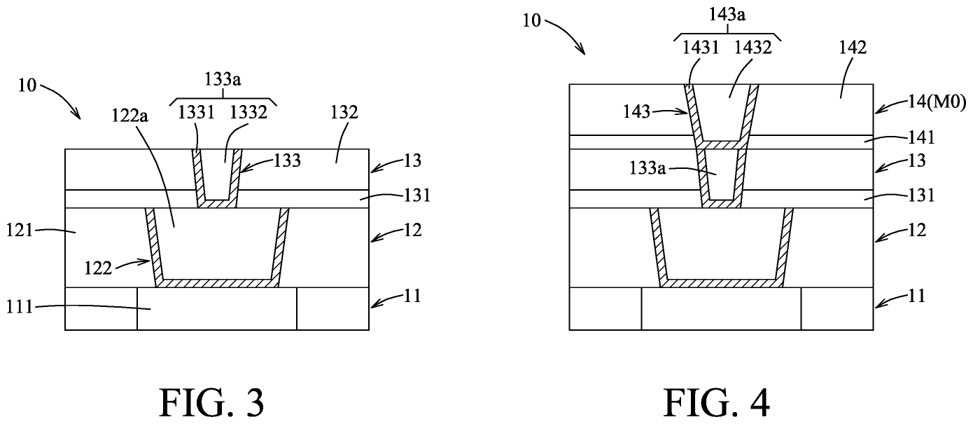

Referring to FIG. 1 and the example illustrated in FIG. 3, the method 100 then proceeds to step 102, where a second interconnect layer is formed on the first interconnect layer. FIG. 3 is a schematic view illustrating formation of a second interconnect layer 13 on the first interconnect layer 12. The second interconnect layer 13 includes an etch stop layer 131 disposed on the first interconnect layer 12, an ILD layer 132 disposed on the etch stop layer 131, and an interconnect structure 133 disposed in the ILD layer 132 and the etch stop layer 131. The interconnect structure 133 includes an interconnect 133a extending through the ILD layer 132 and the etch stop layer 131 to be electrically connected to the interconnect 122a of the first interconnect layer 12. The interconnect 133a includes a bulk metal region 1332 and a single barrier/liner layer 1331 disposed to separate the bulk metal region 1332 from the ILD layer 132 and the etch stop layer 131. In some embodiments, the single barrier/liner layer 1331 has a thickness ranging from about 5 Å to about 50 Å. In some embodiments, the interconnect 133a serves as a via contact disposed on a conductive contact (for example, the interconnect 122a) that is electrically connected to the S/D region 111 in the substrate 11. The interconnect structure 133 is formed in the MEOL process.

In some embodiments, the second interconnect layer 13 may be formed using a single damascene process. The etch stop layer 131 is formed on the first interconnect layer 12 by a suitable deposition process as is known in the art of semiconductor fabrication, such as PVD, CVD, ALD, PEALD, thermal ALD, PECVD, or the like. Other suitable deposition techniques are within the contemplated scope of the present disclosure. In some embodiments, the etch stop layer 131 may include silicon nitride, silicon nitride doped with carbon, silicon oxide, silicon oxynitride, silicon oxynitride doped with carbon, amorphous carbon material, silicon carbide, silicon oxycarbide, other nitride materials, other carbide materials, aluminum oxide, other metal oxides, aluminum nitride, other metal nitrides (e.g., titanium nitride, or the like), boron nitride, boron carbide, and other low-k dielectric materials or low-k dielectric materials doped with one or more of carbon, nitrogen, and hydrogen, or other suitable materials. Other suitable materials are within the contemplated scope of the present disclosure. The ILD layer 132 is then formed on the etch stop layer 131. The material and the process for forming the ILD layer 132 may be the same as or similar to those for forming the ILD layer 121 described above with reference to FIG. 2, and the details thereof are omitted for the sake of brevity. The interconnect structure 133 is then formed using the materials and the processes which are the same as or similar to those for forming the interconnect structure 122 described above with reference to FIG. 2, and the details thereof are omitted for the sake of brevity.

Referring to FIG. 1 and the example illustrated in FIG. 4, the method 100 then proceeds to step 103, where a third interconnect layer is formed on the second interconnect layer. FIG. 4 is a schematic view illustrating formation of a third interconnect layer 14 on the second interconnect layer 13. The third interconnect layer 14 includes an etch stop layer 141 disposed on the second interconnect layer 13, an ILD layer 142 disposed on the etch stop layer 141, and an interconnect structure 143 disposed in the ILD layer 142 and the etch stop layer 141. The interconnect structure 143 includes an interconnect 143a extending through the ILD layer 142 and the etch stop layer 141 to be electrically connected to the interconnect 133a of the second interconnect layer 13. The interconnect 143a includes a bulk metal region 1432 and a single barrier/liner layer 1431 disposed to separate the bulk metal region 1432 from the ILD layer 142 and the etch stop layer 141. In some embodiments, the single barrier/liner layer 1431 has a thickness ranging from about 5 Å to about 50 Å. In some embodiments, the third interconnect layer 14 serves as a metal layer (MO), and the interconnect 143a of the interconnect layer 14 serves a metal line of the metal layer (MO). The interconnect structure 143 is formed in the BEOL process.

In some embodiments, the third interconnect layer 14 may be formed using a single damascene process. The materials and the processes for forming the third interconnect layer 14 may be the same as or similar to those for forming the second interconnect layer 13 described above with reference to FIG. 3, and the details thereof are omitted for the sake of brevity.

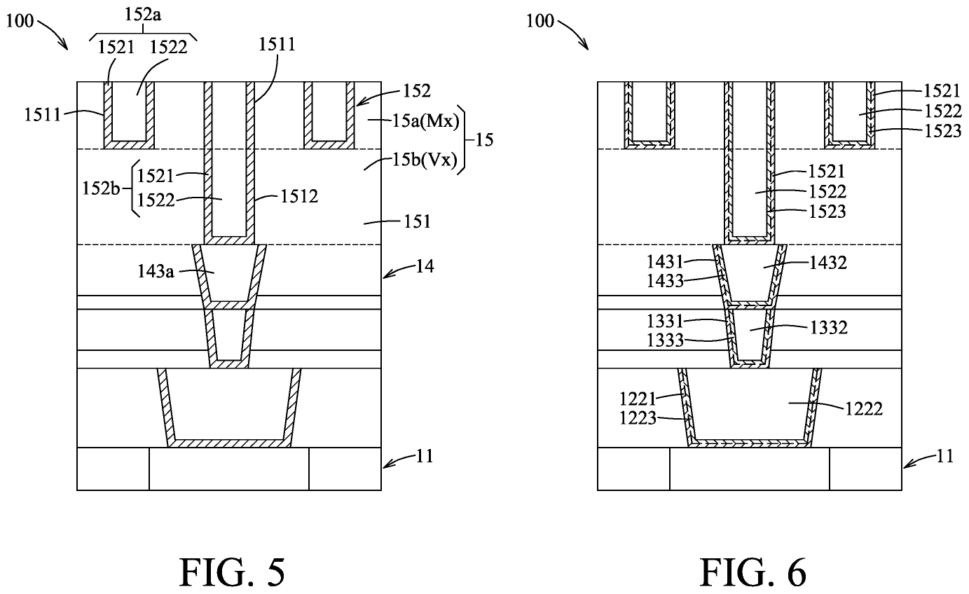

Referring to FIG. 1 and the example illustrated in FIG. 5, the method 100 then proceeds to step 104, where a fourth interconnect layer is formed on the third interconnect layer. FIG. 5 is a schematic view illustrating formation of a fourth interconnect layer 15 on the third interconnect layer 14. The fourth interconnect layer 15 includes an ILD layer 151 disposed on the third interconnect layer 14, and an interconnect structure 152 disposed in the ILD layer 151. The interconnect structure 152 includes a plurality of upper interconnects 152a spaced apart from each other, and a lower interconnect 152b for electrically interconnecting the interconnect 143a of the third interconnect layer 14 with a corresponding one of the upper interconnects 152a. In some embodiments, the fourth interconnect layer 15 includes an upper interconnect sub-layer 15a serving as a metal layer (Mx) and a lower interconnect sub-layer 15b serving as a via layer (Vx). Each of the upper interconnects 152a serves as a metal line of the metal layer (Mx), and the lower interconnect 152b serves a via contact of the via layer (Vx). Each of the upper and lower interconnects 152a, 152b includes a bulk metal region 1522 and a single barrier/liner layer 1521 disposed to separate the bulk metal region 1522 from the ILD layer 151. In some embodiments, the single barrier/liner layer 1521 has a thickness ranging from about 5 Å to about 50 Å. The interconnect structure 152 is formed in the BEOL process.

In some embodiments, the fourth interconnect layer 15 is formed using a dual damascene processes. The ILD layer 151 is formed on the third interconnect layer 14. The material and the process for forming the ILD layer 151 may be the same as or similar to those for forming the ILD layer 121 described above with reference to FIG. 2, and the details thereof are omitted for the sake of brevity.

A plurality of trenches 1511 and a via opening 1512 are formed by patterning the ILD layer 151 using one or more etching processes (for example, but not limited to, a dry etching process, a wet etching process, or a combination thereof) through an opening pattern formed in a patterned mask layer (not shown). The trenches 1511 are recessed downwardly from a top surface of the ILD layer 151, and the via opening 1512 is disposed below and in spatial communication with a corresponding one of the trenches 1511 to form an integrated recess so as to expose the interconnect 143a of the third interconnect layer 14 therethrough. The interconnect structure 152 is then formed in the trenches 1511 and the via opening 1512 using the materials and the processes similar to those for forming the interconnect structure 122 described above with reference with FIG. 2.

Referring to the example illustrated in FIG. 6, in some embodiments, a further single barrier/liner layer 1223 may be formed on the single barrier/liner layer 1221 prior to the formation of the bulk metal region 1222. In some embodiments, the further single barrier/liner layer 1223 and the single barrier/liner layer 1221 are combined with each other to be configured as an integrated layer. In some embodiments, a total thickness of the further single barrier/liner layer 1223 and the single barrier/liner layer 1221 ranges from about 5 Å to about 50 Å. The materials and the processes for forming the further single barrier/liner layer 1223 may be the same as or similar to those for forming the single barrier/liner layer 1221 described above with reference to FIG. 2, and the details thereof are omitted for the sake of brevity. Similarly, a further single barrier/liner layer 1333 may be formed on the single barrier/liner layer 1331 prior to the formation of the bulk metal region 1332, and the further single barrier/liner layer 1333 and the single barrier/liner layer 1331 are combined with each other to be configured as an integrated layer. In some embodiments, a total thickness of the further single barrier/liner layer 1333 and the single barrier/liner layer 1331 ranges from about 5 Å to about 50 Å. A further single barrier/liner layer 1433 may be formed on the single barrier/liner layer 1431 prior to the formation of the bulk metal region 1432, and the further single barrier/liner layer 1433 and the single barrier/liner layer 1431 are combined with each other to be configured as an integrated layer. In some embodiments, a total thickness of the further single barrier/liner layer 1433 and the single barrier/liner layer 1341 ranges from about 5 Å to about 50 Å. A further single barrier/liner layer 1523 may be formed on the single barrier/liner layer 1521 prior to the formation of the bulk metal region 1522, and the further single barrier/liner layer 1523 and the single barrier/liner layer 1521 are combined with each other to be configured as an integrated layer. In some embodiments, a total thickness of the further single barrier/liner layer 1523 and the single barrier/liner layer 1521 ranges from about 5 Å to about 50 Å.

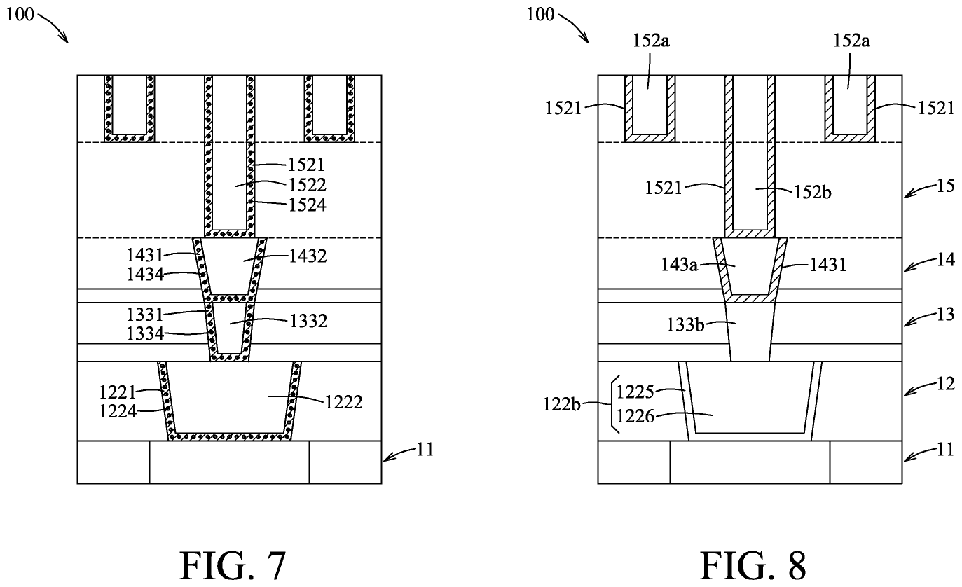

Referring to the example illustrated in FIG. 7, in some embodiments, a composition 1224, which includes the main component and the doping component described above, is doped into the single barrier/liner layer 1221 using a suitable doping process known in the art of semiconductor fabrication, prior to the formation of the bulk metal region 1222. Similarly, a composition 1334, which includes the main component and the doping component described above, is doped into the single barrier/liner layer 1331 prior to the formation of the bulk metal region 1332. A composition 1434, which includes the main component and the doping component described above, is doped into the single barrier/liner layer 1431 prior to the formation of the bulk metal region 1432. A composition 1524, which includes the main component and the doping component described above, is doped into the single barrier/liner layer 1521 prior to the formation of the bulk metal region 1522.

Referring to the example illustrated in FIG. 8, in some embodiments, instead of formation of the interconnect 122a including the single barrier/liner layer 1221, an interconnect 122b, which includes a liner layer 1225 and a bulk metal region 1226, may be formed in the first interconnect layer 12 using the materials and the processes known in the art of semiconductor fabrication. The liner layer 1225 includes, for example, but not limited to, Co, Ru, Ta, or the like, suitable for forming a metal liner layer. Other suitable metal materials are within the contemplated scope of the present disclosure. The bulk metal region 1226 includes, for example, but not limited to, Ag, Au, Al, Ni, Co, Ru, Ir, Pt, Pd, Os, W, Mo, Ta, Cu, or the like, or alloys thereof possessing promising conductive properties. Other suitable metal materials are within the contemplated scope of the present disclosure. Instead of forming the interconnect 133a including the single barrier/liner layer 1331, an interconnect 133b without the single barrier/liner layer 1331 may be formed in the second interconnect layer 13 using the materials and the processes known in the art of semiconductor fabrication. The interconnect 133b includes, for example, but not limited to, Ag, Au, Al, Ni, Co, Ru, Ir, Pt, Pd, Os, W, Mo, Ta, or the like, or alloys thereof possessing promising conductive properties. Other suitable metal materials are within the contemplated scope of the present disclosure. That is, in the embodiments illustrated in FIG. 8, the single barrier/liner layers 1431, 1521 are respectively included in the interconnects 143a, 152a, 152b formed in the BEOL process.

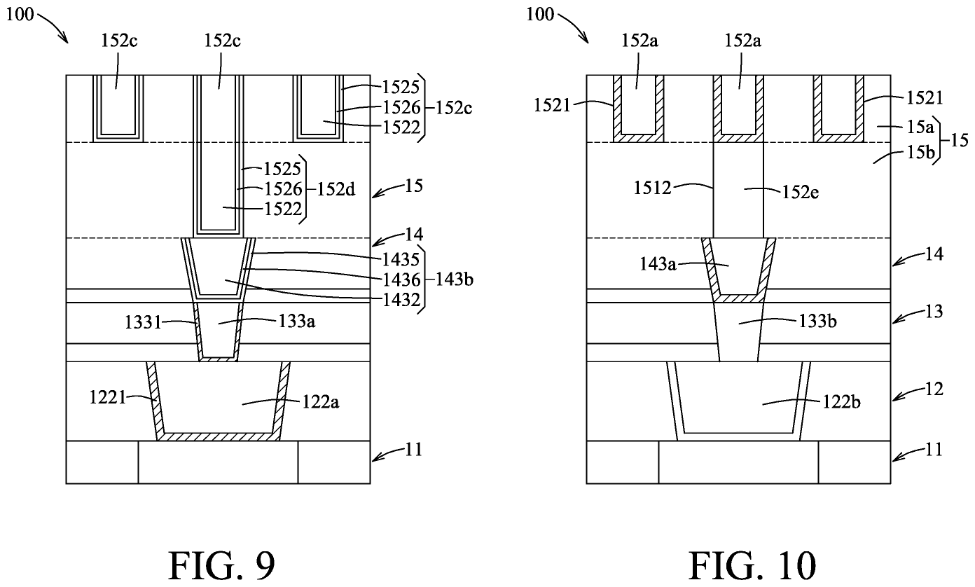

Referring to the example illustrated in FIG. 9, in some embodiments, instead of forming the interconnect 143a including the single barrier/liner layer 1431, an interconnect 143b, which includes a barrier layer 1435, a liner layer 1436, and the bulk metal region 1432, may be formed in the third interconnect layer 14 using the materials and the processes known in the art of semiconductor fabrication. The barrier layer 1435 and the liner layer 1436 are formed separately and sequentially. The barrier layer 1435 may include, for example, but not limited to, Ta, Zn, Mn, Zr, Ti, Hf, Nb, V, Cr, Sc, Y, Si, W, Mo, Al, or the like, suitable for forming a metal barrier layer. Other suitable metal materials are within the contemplated scope of the present disclosure. The liner layer 1436 may include, for example, but not limited to, Co, Ru, Ta, or the like, suitable for forming a metal liner layer. Other suitable metal materials are within the contemplated scope of the present disclosure. Instead of forming the upper and lower interconnects 152a, 152b, each of which includes the single barrier/liner layer 1521, a plurality of upper interconnects 152c and a lower interconnect 152d, each of which includes a barrier layer 1525, a liner layer 1526, and the bulk metal region 1522, may be formed in the fourth interconnect layer 15 using the materials and the processes known in the art of semiconductor fabrication. The barrier layer 1525 and the liner layer 1526 are formed separately and sequentially. The barrier layer 1525 may include, for example, but not limited to, Ta, Zn, Mn, Zr, Ti, Hf, Nb, V, Cr, Sc, Y, Si, W, Mo, Al, or the like, suitable for forming a metal barrier layer. Other suitable metal materials are within the contemplated scope of the present disclosure. The liner layer 1526 may include, for example, but not limited to, Co, Ru, Ta, or the like, suitable for forming a metal liner layer. Other suitable metal materials are within the contemplated scope of the present disclosure. That is, in the embodiments illustrated in FIG. 9, the single barrier/liner layers 1221, 1331 are respectively included the interconnects 122a, 133a formed in the MEOL process.

Referring to the example illustrated in FIG. 10, in some embodiments, the interconnect 122b is formed in the first interconnect layer 12. The interconnect 133b is formed in the second interconnect layer 13. The interconnect 143a is formed in the third interconnect layer 14. The upper interconnects 152a are formed in the upper interconnect sub-layer 15a of the fourth interconnect layer 15. A lower interconnect 152e is formed in the lower interconnect sub-layer 15b of the fourth interconnect layer 15. The interconnect 143a of the third interconnect layer 14 is electrically connected to a corresponding one of the upper interconnects 152a through the lower interconnect 152e. The lower interconnect 152e is formed by filling a metal material (for example, but not limited to, Ag, Au, Al, Ni, Co, Ru, Ir, Pt, Pd, Os, W, Mo, Ta, or the like) in the via opening 1512 prior to the formation of the upper interconnects 152a.

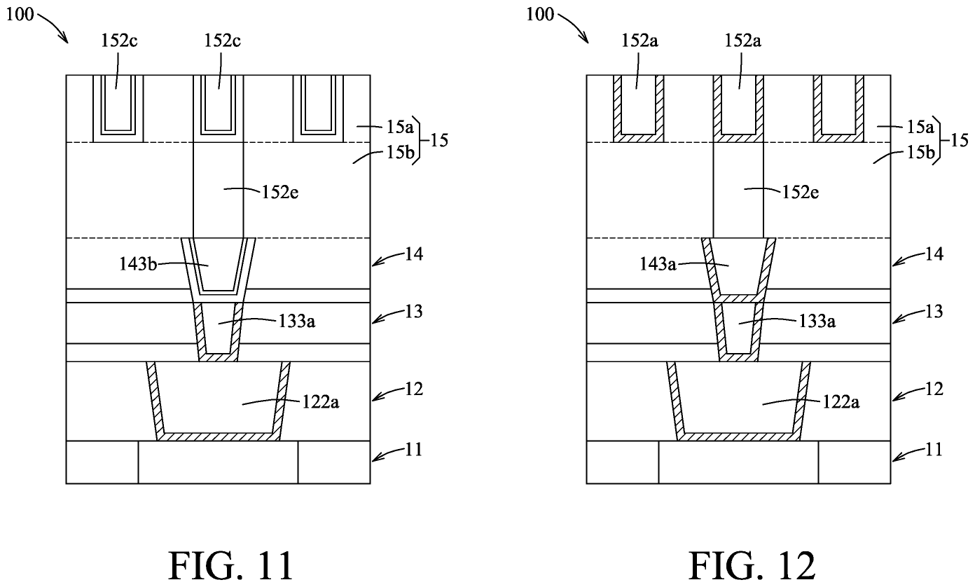

Referring to the example illustrated in FIG. 11, in some embodiments, the interconnect 122a is formed in the first interconnect layer 12. The interconnect 133a is formed in the second interconnect layer 13. The interconnect structure 143b is formed in the third interconnect layer 14. The lower interconnect 152e is formed in the lower interconnect sub-layer 15b of the fourth interconnect layer 15. The upper interconnects 152c are formed in the upper interconnect sub-layer 15a of the fourth interconnect layer 15.

Referring to the example illustrated in FIG. 12, in some embodiments, the interconnect 122a is formed in the first interconnect layer 12. The interconnect 133a is formed in the second interconnect layer 13. The interconnect 143a is formed in the third interconnect layer 14. The interconnect 152e is formed in the lower interconnect sub-layer 15b of the fourth interconnect layer 15. The interconnects 152a are formed in the upper interconnect sub-layer 15a of the fourth interconnect layer 15.

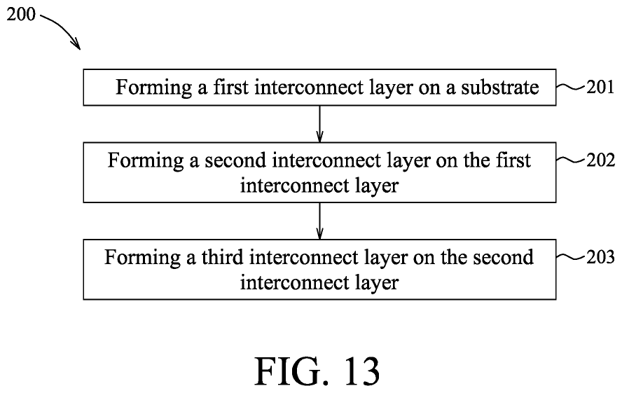

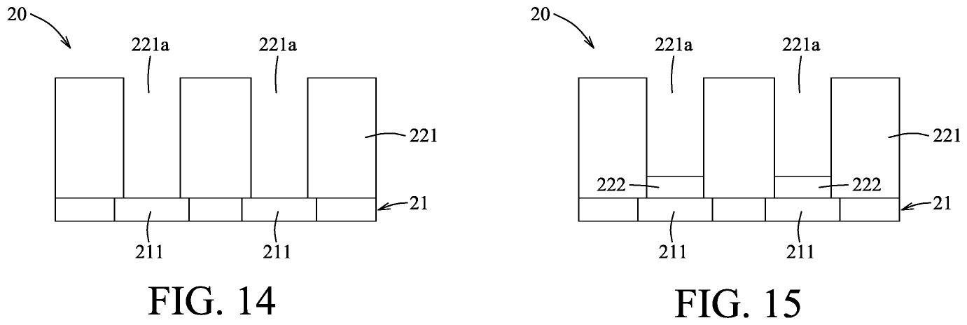

FIG. 13 illustrates a method 200 for manufacturing a semiconductor device in accordance with some embodiments. FIGS. 14 to 21 are schematic views of a semiconductor device 20 at some intermediate stages of the manufacturing method as depicted in FIG. 13 in accordance with some embodiments. Additional steps can be provided before, after or during the method 200, and some of the steps described herein may be replaced by other steps or be eliminated. Similarly, further additional features may be present in the semiconductor device 20, and/or features present may be replaced or eliminated in additional embodiments.

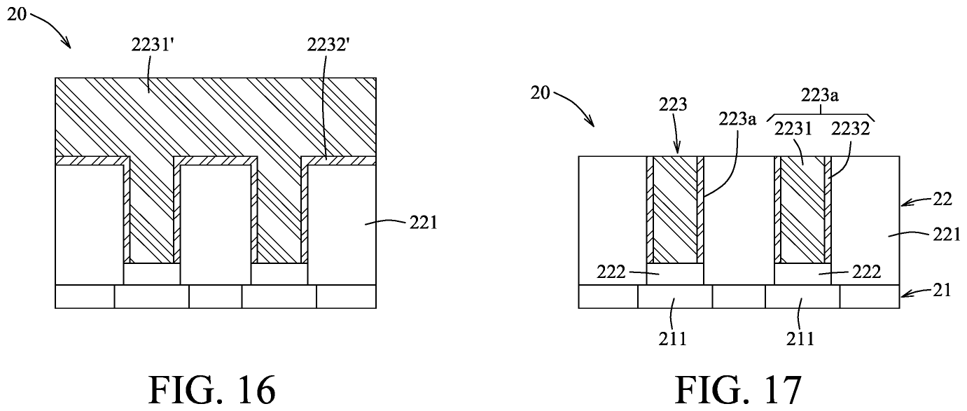

Referring to FIG. 13 and the examples illustrated in FIGS. 14 to 17, the method 200 begins at step 201, where a first interconnect layer is formed on a substrate. FIGS. 14 to 17 are schematic views illustrating some stages of formation of a first interconnect layer 22 on a substrate 21. In some embodiments, the substrate 21 is a semiconductor substrate, which is the same as or similar to that described above for the substrate 11 with reference to FIG. 2, and thus details thereof are omitted for the sake of brevity. Referring to the example illustrated in FIG. 17, the first interconnect layer 22 is formed on the substrate 21, and includes an ILD layer 221, metal silicide regions 222 disposed in a lower portion of the ILD layer 121 and respectively in contact with active regions (for example, but not limited to, S/D regions) 211 disposed in the substrate 21, and an interconnect structure 223 disposed in an upper portion of the ILD layer 221 and in contact with the metal silicide regions 222. The interconnect structure 223 includes a plurality of interconnects 223a which are disposed on the metal silicide regions 222, respectively, and which extend upwardly from the metal silicide regions 222 to terminate at an upper surface of the ILD layer 221. The interconnects 223a serve as conductive contacts for electrically connecting the active regions 211 through the metal silicide regions 222, respectively. Each of the interconnects 223a includes a bulk metal region 2231 and a single barrier/liner layer 2232 disposed to laterally cover the bulk metal region 2231 and to separate the bulk metal region 2231 from the ILD layer 221. The interconnect structure 223 is formed in the MEOL process. In some embodiments, the single barrier/liner layer 2232 has a thickness ranging from about 0.1 nanometer (nm) to about 10 nm. If the thickness is greater than 10 nm, the interconnects 223a may not have superior conductive performance. In some embodiments, the interconnects 223a may have a height ranging from about 1 nm to about 1000 nm.

In some embodiments, the first interconnect layer 22 may be formed using a single damascene processes. Referring to the example illustrated in FIG. 14, the ILD layer 221 is formed on the substrate 21. The material and the process for forming the ILD layer 221 may be the same as or similar to those for forming the ILD layer 121 described above with reference to FIG. 2, and the details thereof are omitted for the sake of brevity. A plurality of openings 221a are formed to extend through the ILD layer 221 so as to expose the active regions 211 therethrough, respectively. The processes for forming the openings 221a may be the same as or similar to those for forming the opening 1211 described above with reference to FIG. 2, and the details thereof are omitted for the sake of brevity.

Referring to the example illustrated in FIG. 15, the metal silicide regions 222 are formed on the active regions 211, respectively, by a suitable formation process known to those skilled in the art of semiconductor fabrication. For example, the metal silicide regions 222 may be formed by a pre-silicidation implantation process in which implant regions are formed, followed by subjecting the implant regions to a silicidation process so as to form the metal silicide regions 222. In the pre-silicidation implantation process, dopants (for example, but not limited to, metal dopants) are implanted through openings 221a. In some embodiments, the silicidation process may include an annealing operation. In some embodiments, the metal silicide regions 222 may include titanium silicide (TiₓSi_{y}), molybdenum silicide (MoₓSi_{y}), nickel silicide (NiₓSi_{y}), ruthenium silicide (RuₓSi_{y}), cobalt silicide (CoₓSi_{y}), tungsten silicide (WₓSi_{y}), europium silicide (EuₓSi_{y}), erbium silicide (ErₓSi_{y}), titanium germanosilicide (TiₓSi_{y}Ge_{z}), molybdenum germanosilicide (MoₓSi_{y}Ge_{z}), nickel germanosilicide (NiₓSi_{y}Ge_{z}), ruthenium germanosilicide (RuₓSi_{y}Ge_{z}), cobalt germanosilicide (CoₓSi_{y}Ge_{z}), tungsten germanosilicide (WₓSi_{y}Ge_{z}), europium germanosilicide (EuₓSi_{y}Ge_{z}), erbium germanosilicide (ErₓSi_{y}Ge_{z}), and the like, or combinations thereof. Other suitable metal silicide materials are within the contemplated scope of the present disclosure.

Referring to the examples illustrated in FIGS. 15 and 16, a composition including a matrix and a self-forming-liner component is filled into the openings 221a and covers the ILD layer 221 by a suitable deposition process as is known to those skilled in the art of semiconductor fabrication, for example, but no limited to, PVD, CVD, ALD, PEALD, PECVD, or the like. Other suitable techniques are within the contemplated scope of the present disclosure. The deposition process may be performed at a temperature ranging from about 25° C. to about 1400° C. If the temperature is greater than 1400° C., the ILD layer 221 and/or the substrate 21 may be damaged. In some embodiments, the matrix includes metals (e.g., Cu, Ag, Au, Ni, Co, iron (Fe), Ru, Os, rhenium (Re), Ir, Pt, Pd, rhodium (Rh), Al, W, Mo), alloys thereof possessing promising conductive properties, or the like. Other suitable metal materials are within the contemplated scope of the present disclosure. In some embodiments, the alloys for the matrix may be a binary, ternary, quarternary, or more element system. In some embodiments, the self-forming-liner component includes a metal (for example, but not limited to, Al, Mn, Ti, Zr, Hf, Nb, Ta, Mo, W, Zn, V, Cr, Sc, Fe, Y, germanium (Ge), gallium (Ga), indium (In), tin (Sn), or the like), alloys of the metals, or silicides or oxides thereof that possess diffusion barrier property. In some embodiments, the self-forming-liner component may be doped as a solid solution, an intermetallic compound, a precipitate phase, or the like. An annealing process is performed to form a bulk metal layer 2231′ and a self-forming liner layer 2232′, which is formed conformally on the ILD layer 221 to separate the bulk metal layer 2231′ from the ILD layer 221. The bulk metal layer 2231′ includes the matrix, and the self-forming liner layer 2232′ includes the self-forming-liner component. The annealing process is performed at a temperature ranging from about 100° C. to about 1400° C. If the temperature is lower than 100° C., the self-forming liner layer 2232′ may not be formed. If the temperature is higher than 1400° C., the ILD layer 221 and/or the substrate 21 may be damaged. The annealing process may be, for example, but not limited to, a rapid thermal annealing (RTA) process, a laser process, a furnace annealing process, or the like. Other suitable annealing techniques are within the contemplated scope of the disclosure. In some embodiments, the annealing process may be performed simultaneously with the filling of the composition by performing the deposition process at a temperature ranging from about 100° C. to about 1400° C. In some embodiments, the annealing process may be performed separately after the the composition is completely filled. A planarization process (for example, but not limited, CMP) is then performed to remove excess of bulk metal layer 2231′ and the excess of the self-forming liner layer 2232′ above the ILD layer 221 so as to form the interconnect structure 223. The interconnect structure 223 formed after the annealing process may have improved crystallinity and reduced resistivity.

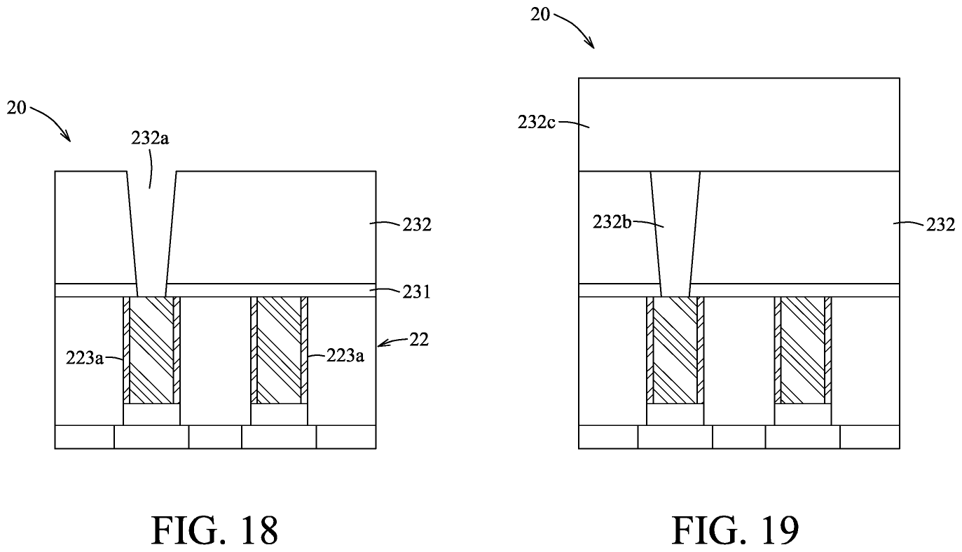

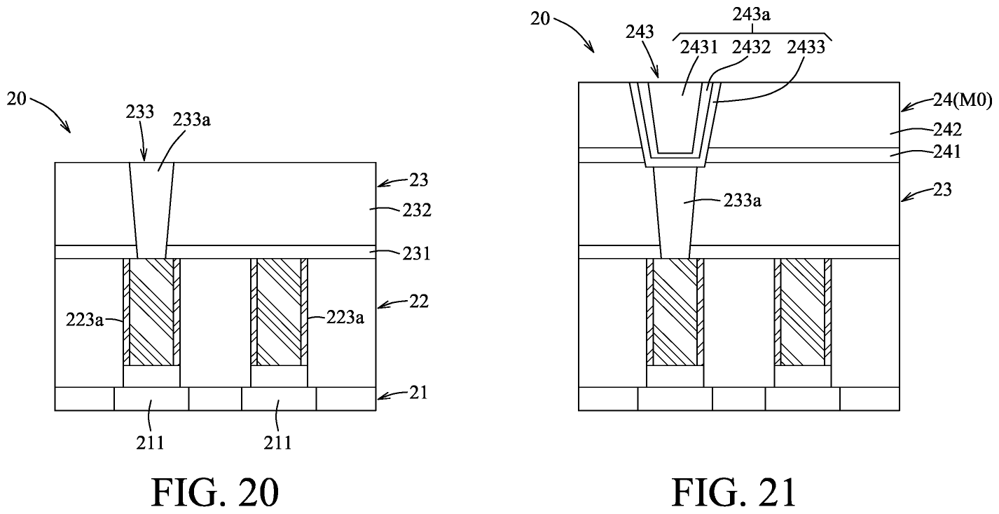

Referring to FIG. 13 and the examples illustrated in FIGS. 18 to 20, the method 200 proceeds to step 202, where a second interconnect layer is formed on the first interconnect layer. FIGS. 18 to 20 are schematic views illustrating some stages of formation of a second interconnect layer 23 on the first interconnect layer 22. Referring to the example illustrated in FIG. 20, the second interconnect layer 23 is disposed on the first interconnect layer 22, and includes an etch stop layer 231 disposed on the first interconnect layer 22, an ILD layer 232 disposed on the etch stop layer 231, and an interconnect structure 233 disposed in the ILD layer 232 and the etch stop layer 231. The interconnect structure 233 includes an interconnect 233a extending through the ILD layer 232 and the etch stop layer 231 to be electrically connected to a corresponding one of the interconnects 223a of the first interconnect layer 22. In some embodiments, the interconnect 233a serves as a via contact disposed on a corresponding one of conductive contacts (for example, the interconnects 223a) that is disposed on S/D regions (for example, the active regions 211) of a transistor (not shown) in the substrate 21. The interconnect structure 233 is formed in the MEOL process.

In some embodiments, the second interconnect layer 23 may be formed using a single damascene process. Referring to the example illustrated in FIG. 18, the etch stop layer 231 is formed on the first interconnect layer 22. The material and the process for forming the etch stop layer 231 may be the same as or similar to those for forming the etch stop layer 131 described above with reference to FIG. 3, and the details thereof are omitted for the sake of brevity. The ILD layer 232 is then formed on the etch stop layer 231. The material and the process for forming the ILD layer 232 may be the same as or similar to those for forming the ILD layer 121 described above with reference to FIG. 2, and the details thereof are omitted for the sake of brevity. An opening 232a is formed to penetrate through the ILD layer 232 and the etch stop layer 231 so as to expose the corresponding one of the interconnects 233a therethrough.

Referring to the examples illustrated in FIGS. 18 and 19, the opening 232a is filled with a metal material 232b, and a metal layer 232c is optionally formed on the ILD layer 232 to cover the metal material 232b so as to successfully perform a subsequent planarization process (for example, CMP). Filling of the metal material 232b and formation of the metal layer 232c may be performed sequentially by a suitable deposition process as is known to those skilled in the art of semiconductor fabrication, for example, but no limited to, PVD, CVD, ALD, PEALD, PECVD, or the like. Other suitable techniques are within the contemplated scope of the present disclosure. In some embodiments, the metal material 232b and the metal layer 232c each may independently include metals (e.g., Cu, Ag, Au, Ni, Co, Fe, Ru, Os, Re, Ir, Pt, Pd, Rh, Al, W, Mo), alloys thereof possessing promising conductive properties, or the like. Other suitable metal materials are within the contemplated scope of the present disclosure. The planarization process (e.g., CMP) is then performed to remove the metal layer 232c and optionally upper portions of the metal material 232b and the ILD layer 232 so as to form the interconnect structure 233.

Referring to FIG. 13 and the example illustrated in FIG. 21, the method 100 then proceeds to step 203, where a third interconnect layer is formed on the second interconnect layer. FIG. 21 is a schematic view illustrating formation of a third interconnect layer 24 on the second interconnect layer 23. The third interconnect layer 24 includes an etch stop layer 241 disposed on the second interconnect layer 23, an ILD layer 242 disposed on the etch stop layer 241, and an interconnect structure 243 disposed in the ILD layer 242 and the etch stop layer 241. The interconnect structure 243 includes an interconnect 243a extending through the ILD layer 242 and the etch stop layer 241 to be electrically connected to the interconnect 233a of the second interconnect layer 23. In some embodiments, the third interconnect layer 24 serves as a metal layer (MO), and the interconnect 243a of the interconnect layer 24 serves a metal line of the metal layer (MO). The interconnect structure 243 is formed in the BEOL process.

In some embodiments, the third interconnect layer 24 may be formed using a single damascene process. The etch stop layer 241 is formed on the second interconnect layer 23. The material and the process for forming the etch stop layer 241 may be the same as or similar to those for forming the etch stop layer 131 described above with reference to FIG. 3, and the details thereof are omitted for the sake of brevity. The ILD layer 242 is then formed on the etch stop layer 241. The material and the process for forming the ILD layer 242 may be the same as or similar to those for forming the ILD layer 121 described above with reference to FIG. 2, and the details thereof are omitted for the sake of brevity. The interconnect structure 243 including the interconnect 243a is then formed using the materials and the processes as are known in the art of semiconductor fabrication. The interconnect 243a includes a bulk metal region 2431, a barrier layer 2433, and a liner layer 2432 disposed between the bulk metal region 2431 and the barrier layer 2433. The barrier layer 2433 and the liner layer 2432 are formed separately and sequentially. The barrier layer 2433 may include, for example, but not limited to, Ta, Zn, Mn, Zr, Ti, Hf, Nb, V, Cr, Sc, Y, Si, W, Mo, Al, or the like, suitable for forming a metal barrier layer. Other suitable metal materials are within the contemplated scope of the present disclosure. The liner layer 2432 may include, for example, but not limited to, Co, Ru, Ta, or the like, suitable for forming a metal liner layer. Other suitable metal materials are within the contemplated scope of the present disclosure.

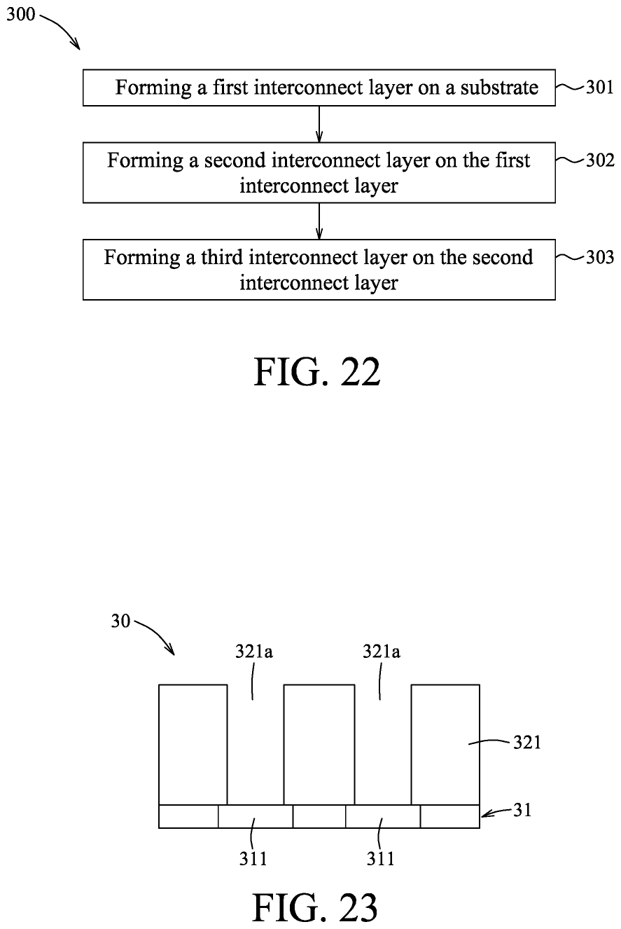

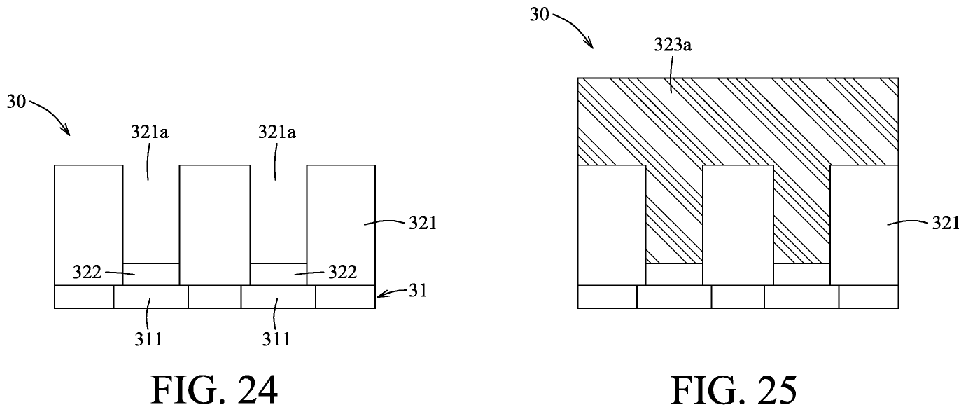

FIG. 22 illustrates a method 300 for manufacturing a semiconductor device in accordance with some embodiments. FIGS. 23 to 31 are schematic views of a semiconductor device 30 at some intermediate stages of the manufacturing method as depicted in FIG. 22 in accordance with some embodiments. Additional steps can be provided before, after or during the method 300, and some of the steps described herein may be replaced by other steps or be eliminated. Similarly, further additional features may be present in the semiconductor device 30, and/or features present may be replaced or eliminated in additional embodiments.

Referring to FIG. 22 and the examples illustrated in FIGS. 23 to 27, the method 300 begins at step 301, where a first interconnect layer is formed on a substrate. FIGS. 23 to 27 are schematic views illustrating some stages of formation of a first interconnect layer 32 on a substrate 31. In some embodiments, the substrate 31 is a semiconductor substrate, which is the same as or similar to that described above for the substrate 11 with reference to FIG. 2, and thus details thereof are omitted for the sake of brevity. Referring to the example illustrated in FIG. 27, the first interconnect layer 32 is formed on the substrate 31, and includes an ILD layer 321, metal silicide regions 322 disposed in a lower portion of the ILD layer 321 and respectively in contact with active regions 311 (for example, but not limited to, S/D regions) disposed in the substrate 31, an interconnect structure 323 disposed in an upper portion of the ILD layer 321 and in contact with the metal silicide regions 322, and a capping layer 324 disposed on the interconnect structure 323. The interconnect structure 323 includes a plurality of interconnects 323a, which are disposed on the metal silicide regions 322, respectively. The interconnects 323a serve as conductive contacts for electrically connecting the active regions 311 through the metal silicide regions 322, respectively. Each of the interconnects 323a includes a bulk metal region 3231 and a single barrier/liner layer 3232 disposed to laterally cover the bulk metal region 3231 and separate the bulk metal regions 3231 from the ILD layer 321. The capping layer 324 includes a plurality of capping portions 3421, each of which is disposed on a corresponding one of the interconnects 323a and is formed integrally with the single barrier/liner layer 3232 of the corresponding one of the interconnects 323a. The interconnect structure 323 is formed in the MEOL process. In some embodiments, the single barrier/liner layer 3232 has a thickness ranging from about 0.1 nm to about 10 nm. If the thickness is greater than 10 nm, the interconnects 323a may not have superior conductive performance. In some embodiments, the interconnects 323a may have a height ranging from about 1 nm to about 1000 nm.

In some embodiments, the first interconnect layer 32 may be formed using a single damascene processes. Referring to the example illustrated in FIG. 23, the ILD layer 321 is formed on the substrate 31. The material and the process for forming the ILD layer 321 may be the same as or similar to those for forming the ILD layer 121 described above with reference to FIG. 2, and the details thereof are omitted for the sake of brevity. A plurality of openings 321a are formed to extend through the ILD layer 321 so as to expose the active regions 311 therethrough, respectively. The processes for forming the openings 321a may be the same as or similar to those for forming the opening 1211 described above with reference to FIG. 2, and the details thereof are omitted for the sake of brevity.

Referring to the example illustrated in FIG. 24, the metal silicide regions 322 are formed on the active regions 311, respectively. The material and the process for forming the metal silicide regions 322 may be the same as or similar to those for forming the metal silicide regions 222 described above with reference to FIG. 15, and the details thereof are omitted for the sake of brevity. Referring to the examples illustrated in FIGS. 24 to 26, a composition including a matrix and a self-forming-liner component is filled into the openings 321a and covers the ILD layer 321 by a suitable deposition process described above with respect to FIG. 16. The matrix and the self-forming-liner component may be the same as or similar to those described above with reference to FIG. 16, and the details thereof are omitted for the sake of brevity. A planarization process (for example, CMP) is performed to remove excess of the composition above the ILD layer 221. The composition remaining in the openings 321a is subjected to an annealing process so as to form the interconnect structure 323 and the capping layer 324 simultaneously. The single barrier/liner layer 3232 of each of the interconnects 323a and a corresponding one of the capping portions 3241 are formed integrally by the annealing process. The annealing process is performed at a temperature ranging from about 100° C. to about 1400° C. If the temperature is lower than 100° C., the single barrier/liner layer 3232 of each of the interconnects 323a and the capping layer 324 may not be formed. If the temperature is higher than 1400° C., the ILD layer 221 and/or the substrate 21 may be damaged.

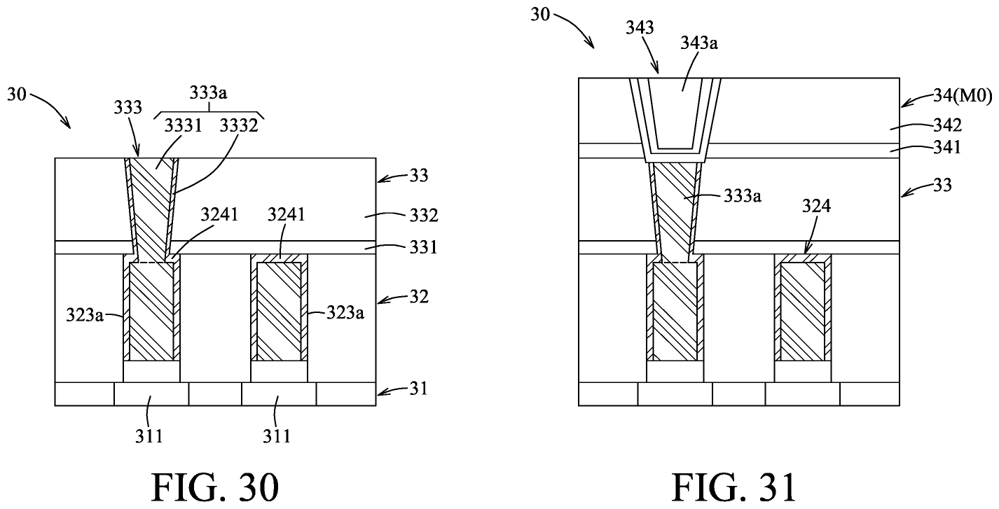

Referring to FIG. 22 and the examples illustrated in FIGS. 27 to 30, the method 200 proceeds to step 302, where a second interconnect layer is formed on the first interconnect layer. FIGS. 27 to 30 are schematic views illustrating some stages of formation of a second interconnect layer 33 on the first interconnect layer 32. Referring to the example illustrated in FIG. 30, the second interconnect layer 33 is disposed on the first interconnect layer 32, and includes an etch stop layer 331 disposed on the first interconnect layer 32, an ILD layer 332 disposed on the etch stop layer 331, and an interconnect structure 333 disposed in the ILD layer 332 and the etch stop layer 331. The interconnect structure 333 includes an interconnect 333a extending through the ILD layer 332, the etch stop layer 331, and a corresponding one of the capping regions 3241 to be electrically connected to a corresponding one of the interconnects 323a of the first interconnect layer 32. In some embodiments, the interconnect 333a serves as a via contact disposed on a corresponding one of conductive contacts (for example, the interconnects 323a) that is disposed on source/drain regions (for example, the active regions 311) of a transistor (not shown) in the substrate 31. The interconnect structure 333 is formed in the MEOL process.

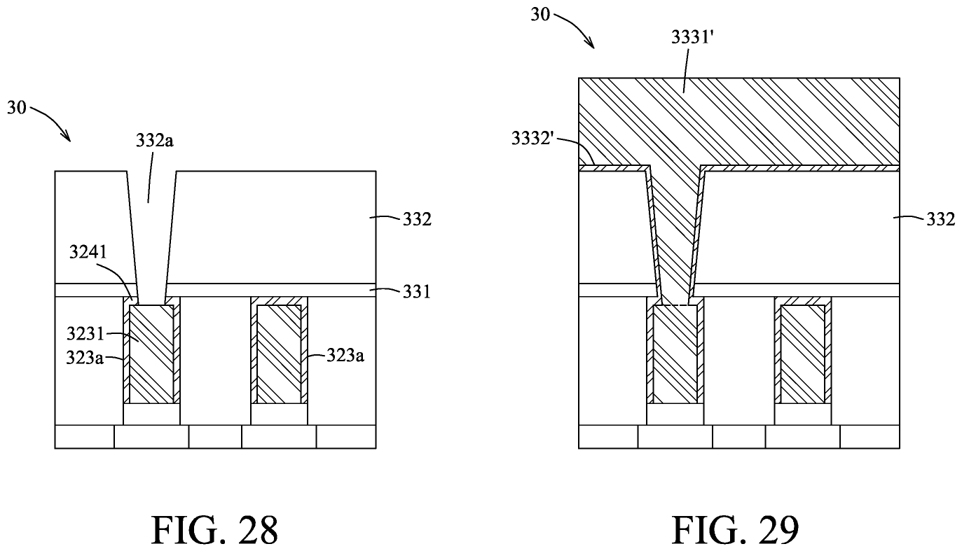

In some embodiments, the second interconnect layer 33 may be formed using a single damascene process. Referring to the examples illustrated in FIGS. 27 and 28, the etch stop layer 331 is formed on the first interconnect layer 32. The material and the process for forming the etch stop layer 331 may be the same as or similar to those for forming the etch stop layer 131 described above with reference to FIG. 3, and the details thereof are omitted for the sake of brevity. The ILD layer 332 is then formed on the etch stop layer 331. The material and the process for forming the ILD layer 332 may be the same as or similar to those for forming the ILD layer 121 described above with reference to FIG. 2, and the details thereof are omitted for the sake of brevity. An opening 332a is formed to penetrate through the ILD layer 332, the etch stop layer 331, and the corresponding one of the capping regions 3241 so as to expose the corresponding one of the interconnects 323a therethrough.

Referring to the examples illustrated in FIGS. 28 and 29, a composition including the matrix and the self-forming-liner component described above with reference to FIG. 16 is filled into the openings 332a and covers the ILD layer 332 by a suitable deposition process described above with reference with FIGS. 15 and 16. An annealing process, which is the same or similar to that described above with reference with FIG. 16, is performed to form a bulk metal layer 3331′ and a self-forming liner layer 3332′ that is formed conformally on the ILD layer 332 to separate the bulk metal layer 3331′ from the ILD layer 332. The bulk metal layer 3331′ includes the matrix, and the self-forming liner layer 3332′ includes the self-forming-liner component. Referring to the examples illustrated in FIGS. 29 and 30, a planarization process (e.g., CMP) is then performed to remove excess of the bulk metal layer 3331′ and excess of the self-forming liner layer 3332′ above the ILD layer 332 so as to form the interconnect structure 333. The interconnect structure 333 formed after the annealing process may have improved crystallinity and reduced resistivity.

Referring to FIG. 22 and the example illustrated in FIG. 31, the method 300 then proceeds to step 303, where a third interconnect layer is formed on the second interconnect layer. FIG. 31 is a schematic view illustrating formation of a third interconnect layer 34 on the second interconnect layer 33. The third interconnect layer 34 includes an etch stop layer 341 disposed on the second interconnect layer 33, an ILD layer 342 disposed on the etch stop layer 341, and an interconnect structure 343 disposed in the ILD layer 342 and the etch stop layer 341. The interconnect structure 343 includes an interconnect 343a extending through the ILD layer 342 and the etch stop layer 341 to be electrically connected to the interconnect 333a of the second interconnect layer 33. In some embodiments, the third interconnect layer 34 serves as a metal layer (MO), and the interconnect 343a of the third interconnect layer 34 serves a metal line of the metal layer (MO). The interconnect structure 343 is formed in the BEOL process. Formation of the third interconnect layer 34 is the same as or similar to that of the third interconnect layer 24 described above with reference with FIG. 21, and the details thereof are omitted for the sake of brevity. In some embodiments, the interconnect structure 343 may be formed using a reactive ion etching process.

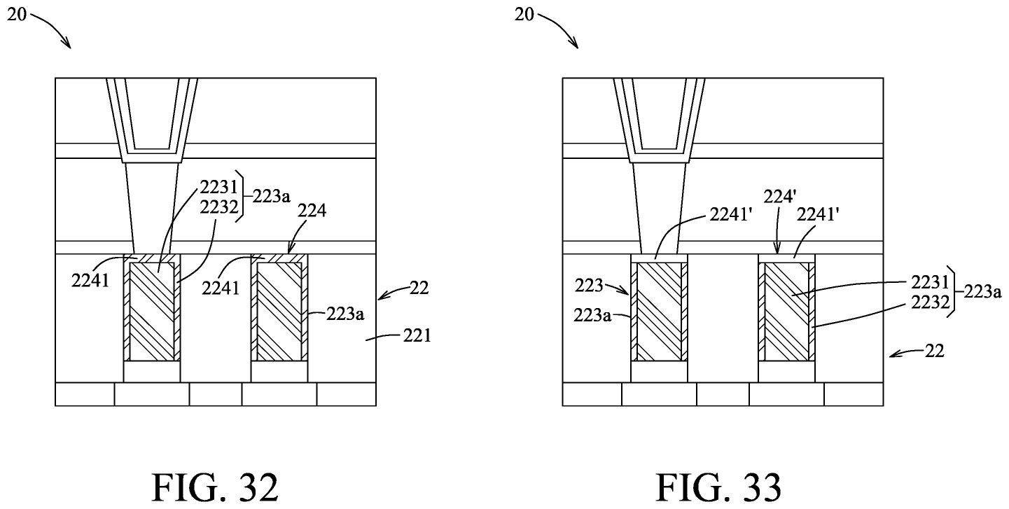

Referring to the example illustrated in FIG. 32, the semiconductor device 20 in some alternative embodiments is similar to that illustrated in FIG. 21 except that the first interconnect layer 22 of the semiconductor device 20 further includes a capping layer 224 including a plurality of capping portions 2241, each of which is disposed on a corresponding one of the interconnects 223a and is formed integrally with the single barrier/liner layer 2232 of the corresponding one of the interconnects 223a. Each of the capping portions 2241 is formed integrally with the single barrier/liner layer 2232 of each of the interconnects 223a by the annealing process described above with reference to FIG. 16, but the annealing process is performed after the planarization process that removes excess of the composition above the ILD layer 221.

Referring to the example illustrated in FIG. 33, a semiconductor device 20 in some alternative embodiments is similar to that illustrated in FIG. 21 except that the first interconnect layer 22 of the semiconductor device 20 further includes a capping layer 224′ which is deposited on the interconnect structure 223 after the interconnect structure 223 is completely formed. The capping layer 224′ includes a plurality of capping portions 2241′ deposited on the interconnects 223a, respectively. The capping layer 224′ may be selectively formed on the interconnects 223a by a suitable selective deposition process as is known to those skilled in the art of semiconductor fabrication, for example, but no limited to, selective CVD, selective ALD, selective electroless deposition (ELD), or the like. Other suitable techniques are within the contemplated scope of the present disclosure. In some embodiments, the capping layer 224′ may include, for example, but not limited to, metal (for example, but not limited to, Co, Al, Ru, W, Mo, Ta, Cu, Fe, Rh, Ir, Pd, Pt, or the like), alloys of the metals, silicides, nitrides, or oxides of the metals or the alloys, or combinations thereof. Other suitable materials are within the contemplated scope of the present disclosure. In some embodiments, the capping layer 224′ may have a thickness ranging from about 0.1 nm to about 30 nm.

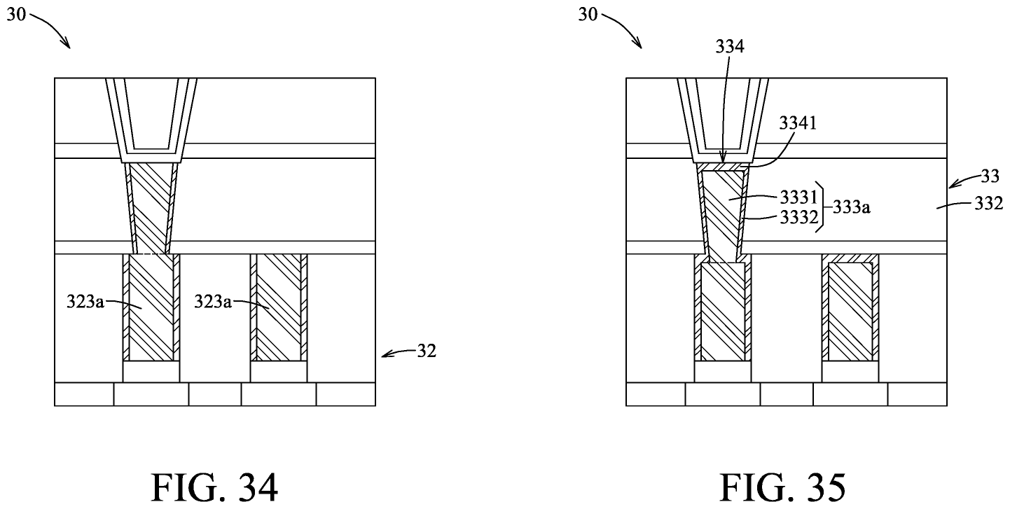

Referring to the example illustrated in FIG. 34, the semiconductor device 30 in some alternative embodiments is similar to that illustrated in FIG. 31 except that the first interconnect layer 32 of the semiconductor device 30 does not include the capping layer 324, which is included in the first interconnect layer 32 of the semiconductor device 30 illustrated in FIG. 31. The interconnects 323a in the first interconnect layer 32 of the semiconductor device 30 illustrated in FIG. 34 is formed by performing the planarization process after the annealing process.

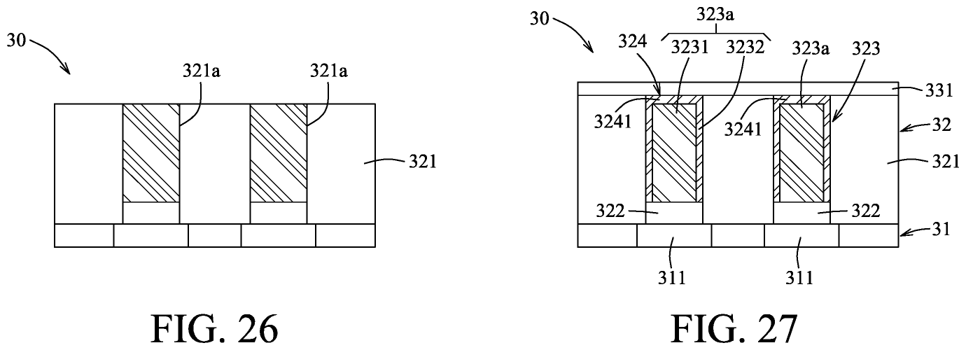

Referring to the example illustrated in FIG. 35, the semiconductor device 30 in some alternative embodiments is similar to that illustrated in FIG. 31 except that the second interconnect layer 33 of the semiconductor device 30 further includes a capping layer 334, which includes a capping portion 3341 formed integrally with the single barrier/liner layer 3332 using the process for forming the capping layer 324 described above with reference to FIGS. 26 and 27. The capping portion 3341 is disposed on the interconnect 333a.

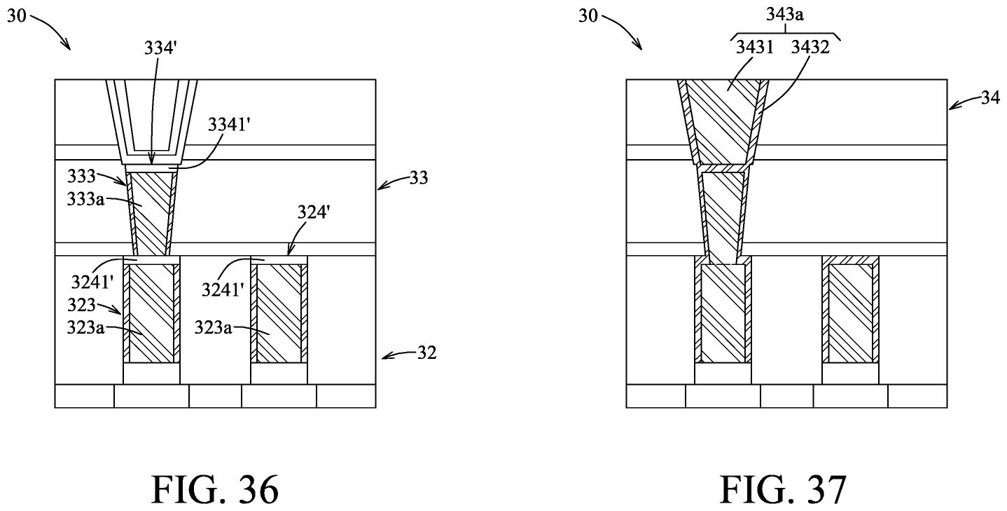

Referring to the example illustrated in FIG. 36, a semiconductor device 30 in some alternative embodiments is similar to that illustrated in FIG. 34 except for the following differences. The first interconnect layer 32 further includes a capping layer 324′, which is deposited on the interconnect structure 323 after the interconnect structure 323 is completely formed. The capping layer 324′ includes a plurality of capping portions 3241′ deposited on the interconnects 323a, respectively. The second interconnect layer 33 further includes a capping layer 334′, which is deposited on the interconnect structure 33 after the interconnect structure 333 is completely formed. The capping layer 334′ includes a capping portion 3341′ deposited on the interconnect 333a. Formation of the capping layers 324′, 334′ is the same as or similar to that of the capping layer 224′ described above with reference with FIG. 33, and the details thereof are omitted for the sake of brevity.

Referring to the example illustrated in FIG. 37, a semiconductor device 30 in some alternative embodiments is similar to that illustrated in FIG. 35 except that the interconnect 343a in the third interconnect layer 343a includes a bulk metal region 3431 and a single barrier/liner layer 3432 disposed to laterally cover the bulk metal region 3431. Formation of the interconnect 343a is the same as or similar to that of the interconnect 333a described above with reference with FIGS. 28 to 30, and the details thereof are omitted for the sake of brevity.

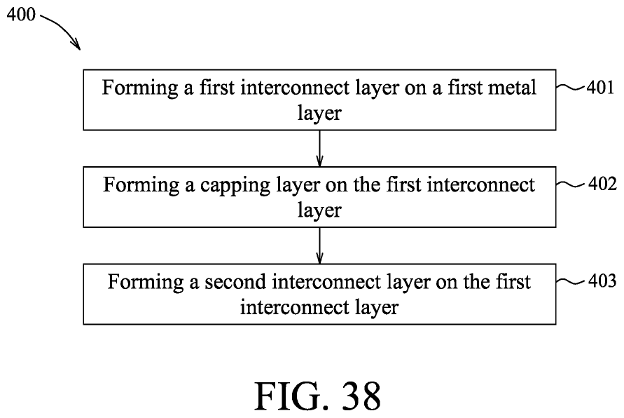

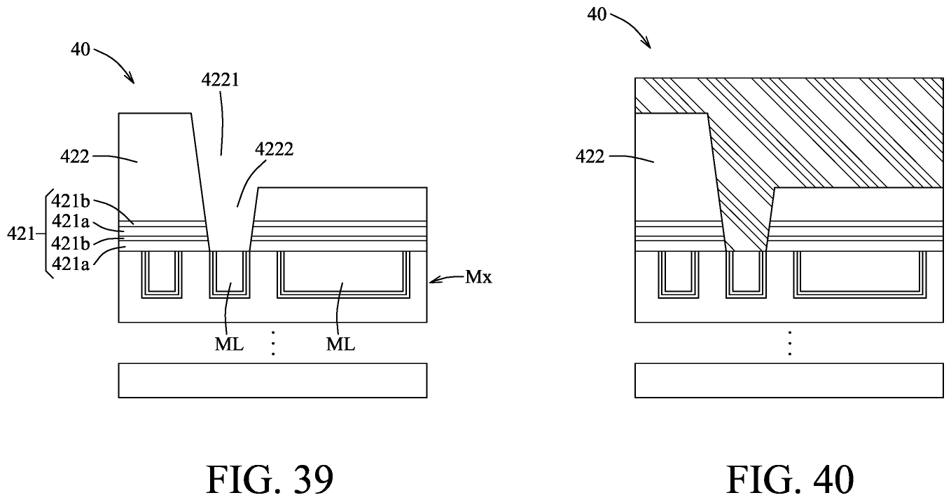

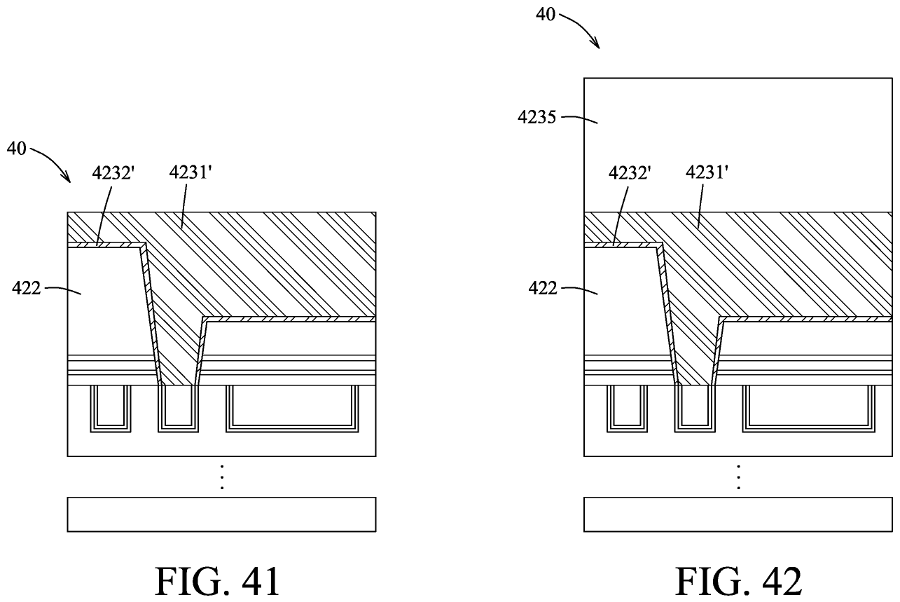

FIG. 38 illustrates a method 400 for manufacturing a semiconductor device in accordance with some embodiments. FIGS. 39 to 46 are schematic views of a semiconductor device 40 at some intermediate stages of the manufacturing method as depicted in FIG. 38 in accordance with some embodiments. Additional steps can be provided before, after or during the method 400, and some of the steps described herein may be replaced by other steps or be eliminated. Similarly, further additional features may be present in the semiconductor device 40, and/or features present may be replaced or eliminated in additional embodiments.

Referring to FIG. 38 and the examples illustrated in FIGS. 39 to 44, the method 400 begins at step 401, where a first interconnect layer is formed on a first metal layer. FIGS. 39 to 44 are schematic views illustrating some stages of formation of a first interconnect layer 42 on a first metal layer (Mx) disposed over a substrate 41. In some embodiments, the substrate 41 is a semiconductor substrate, which is the same as or similar to that described above for the substrate 11 with reference to FIG. 2, and thus details thereof are omitted for the sake of brevity. The first metal layer (Mx) includes a plurality of metal lines (ML) spaced apart from each other. Referring to the example illustrated in FIG. 44, the first interconnect layer 42 is formed on the first metal layer (Mx), and includes at least one etch stop layer 421 disposed on the first metal layer (Mx), an ILD layer 422 disposed on the at least one etch stop layer 421, and an interconnect structure 423 disposed in the ILD layer 422 and the at least one etch stop layer 421. The at least one etch stop layer 421 includes a stack assembly of at least one first etch stop layers 421a and at least one second etch stop layer 421b which are alternately stacked on the first metal layer (Mx). In some embodiments, the number of the at least one first etch stop layer 421a is two, and the number of the at least one second etch stop layer 421b is two. In some embodiments, the number of the at least one first etch stop layer 421a is one, and the number of the at least one second etch stop layer 421b is one. The interconnect structure 423 includes an interconnect 423a extending through the ILD layer 422 and the at least one etch stop layer 421 to be electrically connected to a corresponding one of the metal lines (ML) of the first metal layer (Mx). The interconnect 423a includes a bulk metal region 4231 and a single barrier/liner layer 4232 disposed to separate the bulk metal region 4231 from the ILD layer 422 and the at least one etch stop layer 421.

In some embodiments, the first interconnect layer 42 is formed using a dual damascene process in the BEOL process. Referring to the example illustrated in FIG. 39, the first and second etch stop layers 421a, 421b are deposited alternately on the first metal layer (Mx). The material and the process for forming each of the first and second etch stop layers 421a, 421b are the same as or similar to those for forming the etch stop layer 131 described above with reference to FIG. 3, and the details thereof are omitted for the sake of brevity. The material for the first etch stop layer 421a and the material for the second etch stop layer 421b are different from each other. The ILD layer 422 is then formed on an uppermost one of the first and second etch stop layers 421a, 421b. The material and the process for forming the ILD layer 422 may be the same as or similar to those for forming the ILD layer 121 described above with reference to FIG. 2, and the details thereof are omitted for the sake of brevity.

A trench 4221 and a via opening 4222 are formed by patterning the ILD layer 422 and the first and second etch stop layers 421a, 421b using one or more etching processes (for example, but not limited to, a dry etching process, a wet etching process, or a combination thereof) through an opening pattern formed in a patterned mask layer (not shown). The trench 4221 is recessed downwardly from a top surface of the ILD layer 422, and the via opening 4222 is disposed below and in spatial communication with the trench 4221, so as to form an integrated recess to expose a corresponding one of the metal lines (ML) therethrough.

Referring to the examples illustrated in FIGS. 39 to 41, a composition including the matrix and the self-forming-liner component described above with reference to FIG. 16 is filled into the via opening 4222 and the trench 4221, and covers the ILD layer 422. An annealing process is performed to form a bulk metal layer 4231′ and a self-forming liner layer 4232′, which is formed conformally on the ILD layer 422 and which is disposed to separate the bulk metal layer 4231′ from the ILD layer 422. Formation of the bulk metal layer 4231′ and the self-forming liner layer 4232′ is the same as or similar to that of the bulk metal layer 2231′ and the self-forming liner layer 2232′ described above with reference to FIGS. 15 and 16, and the details thereof are omitted for the sake of brevity.

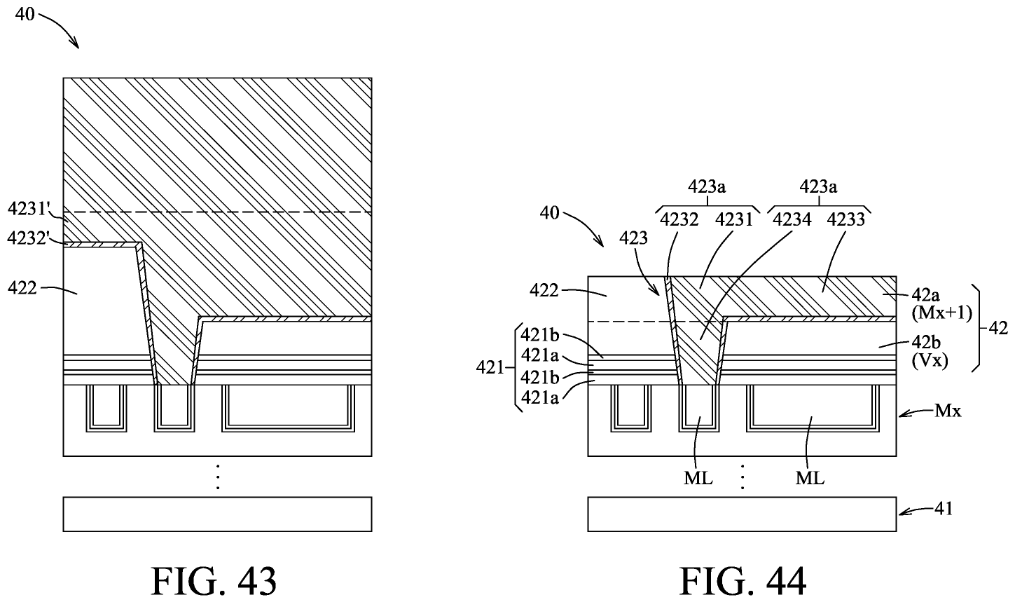

Referring to the examples illustrated in FIGS. 42 to 44, a metal layer 4235 is formed on the bulk metal layer 4231′, as illustrated in FIG. 42 or the composition including the matrix and the self-forming-liner component is further deposited on the bulk metal layer 4231′, as illustrated in FIG. 43. The material and the process for forming the metal layer 4235 are the same as or similar to those for forming the metal layer 232c described above with reference to FIG. 19, and the details thereof are omitted for the sake of brevity. A planarization process (for example, but not limited to, CMP) is performed to remove the metal layer 4235 and portions of the bulk metal layer 4231′, the self-forming liner layer 4232′, and the ILD layer 422 illustrated in FIG. 42, or to remove the composition and portions of the bulk metal layer 4231′, the self-forming liner layer 4232′, and the ILD layer 422 illustrated in FIG. 43, so as to form the first interconnect layer 42. The first interconnect layer 42 includes an upper interconnect sub-layer 42a serving as a second metal layer (Mx+1), and a lower interconnect sub-layer 42b serving as a first via layer (Vx). The interconnect 423a includes an upper interconnect portion 4233 serving a metal line of the second metal layer (Mx+1), and a lower interconnect portion 4234 serving a via contact of the first via layer (Vx).

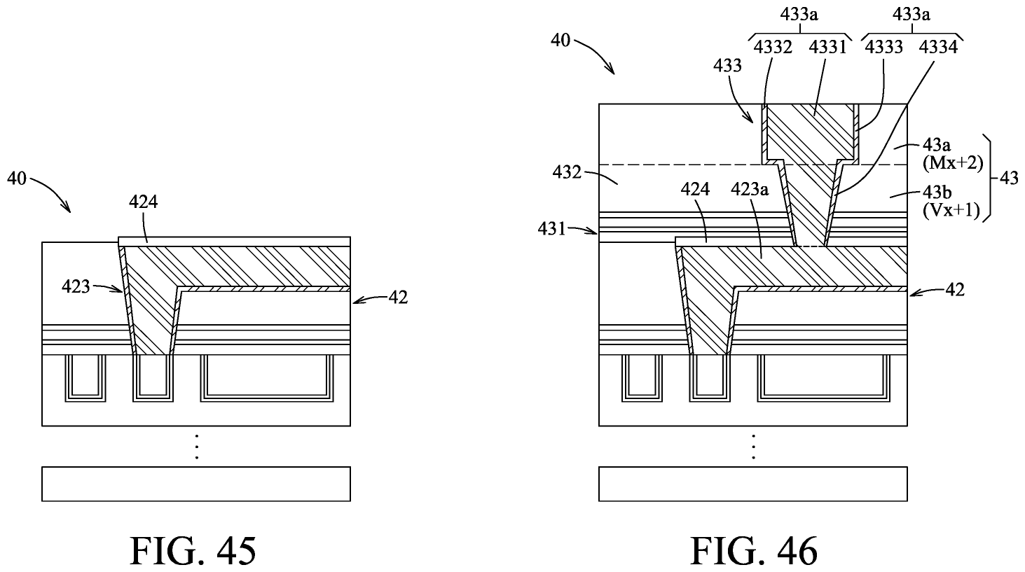

Referring to FIG. 38 and the example illustrated in FIG. 45, the method 400 proceeds to step 402, where a capping layer is formed on the first interconnect layer. FIG. 45 illustrates formation of a capping layer 424 on the first interconnect layer 42 to cover the interconnect structure 423. The material and the process for forming the capping layer 424 may be the same as or similar to those for forming the capping layer 224′ described above with reference to FIG. 33, and the details thereof are omitted for the sake of brevity.

Referring to FIG. 38 and the example illustrated in FIG. 46, the method 400 proceeds to step 403, where a second interconnect layer is formed on the first interconnect layer. FIG. 46 illustrates formation of a second interconnect layer 43 on the first interconnect layer 42. The second interconnect layer 43 includes at least one etch stop layer 431 disposed on the first interconnect layer 42 and the capping layer 424, an ILD layer 432 disposed on the at least one etch stop layer 431, and an interconnect structure 433 disposed in the ILD layer 432 and the at least one etch stop layer 431. The stack configuration of the at least one etch stop layer 431 is the same as or similar to that of the at least one etch stop layer 421 described above with reference to FIG. 44. The interconnect structure 433 includes an interconnect 433a extending through the ILD layer 432, the at least one etch stop layer 431, and the capping layer 424 to be electrically connected to the interconnect 423a of the first interconnect layer 42. The interconnect 433a includes a bulk metal region 4331 and a single barrier/liner layer 4332 disposed to separate the bulk metal region 4331 from the ILD layer 432 and the at least one etch stop layer 431. The second interconnect layer 43 includes an upper interconnect sub-layer 43a serving as a third metal layer (Mx+2), and a lower interconnect sub-layer 43b serving as a second via layer (Vx+1). The interconnect 433a includes an upper interconnect portion 4333 serving a metal line of the third metal layer (Mx+2), and a lower interconnect portion 4334 serving a via contact of the second via layer (Vx+1). The process for forming the second interconnect layer 43 is the same as or similar to that for forming the first interconnect layer 42, and details thereof are omitted for the sake of brevity.

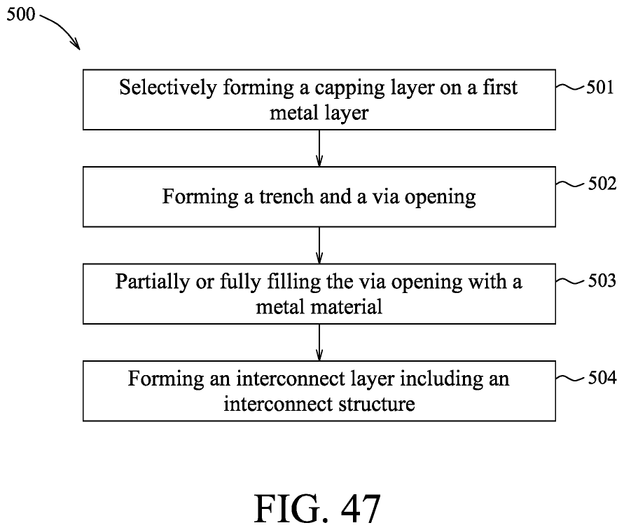

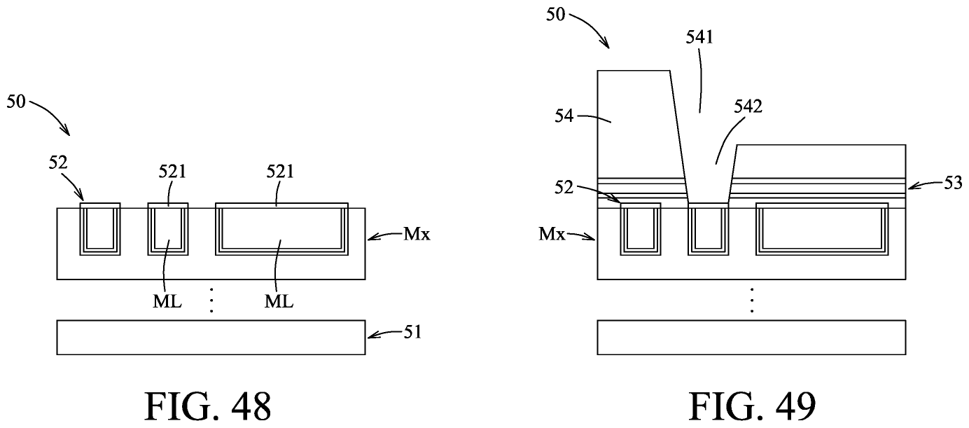

FIG. 47 illustrates a method 500 for manufacturing a semiconductor device in accordance with some embodiments. FIGS. 48 to 55 are schematic views of a semiconductor device 50 at some intermediate stages of the manufacturing method as depicted in FIG. 47 in accordance with some embodiments. Additional steps can be provided before, after or during the method 500, and some of the steps described herein may be replaced by other steps or be eliminated. Similarly, further additional features may be present in the semiconductor device 50, and/or features present may be replaced or eliminated in additional embodiments.

Referring to FIG. 47 and the example illustrated in FIG. 48, the method 500 begins at step 501, where a capping layer is selectively formed on a first metal layer. FIG. 48 is a schematic view illustrating formation of a capping layer 52 on a first metal layer (Mx) disposed over a substrate 51. In some embodiments, the substrate 51 is a semiconductor substrate, which is the same as or similar to that described above for the substrate 11 with reference to FIG. 2, and thus details thereof are omitted for the sake of brevity. The first metal layer (Mx) includes a plurality of metal lines (ML) spaced apart from each other. The capping layer 52 may be selectively formed on the first metal layer (Mx) using the material and the selective deposition process described above for forming the capping layer 224′ with reference to FIG. 33, such that a plurality of capping portions 521 of the capping layer 52 are selectively deposited on the metal lines (ML) of the first metal layer (Mx), respectively.

Referring to FIG. 47 and the example illustrated in FIG. 49, the method 500 proceeds to step 502, where a trench and a via opening are formed. A dual damascene process is then used to form an interconnect layer with an interconnect structure. FIG. 49 is a schematic view illustrating formation of a trench 541 and a via opening 542 in an ILD layer 54 and at least one etch stop layer 53. The stack configuration, the material, and the manufacturing process of the at least one etch stop layer 53 are the same as or similar to those of the at least one etch stop layer 421 described above with reference to FIGS. 39 and 44. The ILD layer 54 is then deposited on the at least one etch stop layer 53. The material and the process for forming the ILD layer 54 may be the same as or similar to those for forming the ILD layer 121 described above with reference to FIG. 2, and the details thereof are omitted for the sake of brevity. The trench 541 and the via opening 542 are formed using one or more etching processes (for example, but not limited to, a dry etching process, a wet etching process, or a combination thereof) through an opening pattern formed in a patterned mask layer (not shown). The trench 541 is recessed downwardly from a top surface of the ILD layer 54, and the via opening 542 is disposed below and in spatial communication with the trench 541 so as to form an integrated recess to expose a corresponding one of the metal lines (ML) therethrough.

Referring to FIG. 47 and the examples illustrated in FIGS. 49 to 51, the method 500 proceeds to step 503, where the via opening is partially or fully filled with a metal material. A metal material 55 may be selectively filled into the via opening 542 to completely cover the via opening 542 so as to form a via contact. Alternatively, the metal material may be selectively filled into the via opening 542 to partially cover the via opening 542 so as form a lower portion of the via contact. The material and the process for filling the metal material 55 may be the same as or similar to those described above with reference to FIG. 2, and the details thereof are omitted for the sake of brevity.

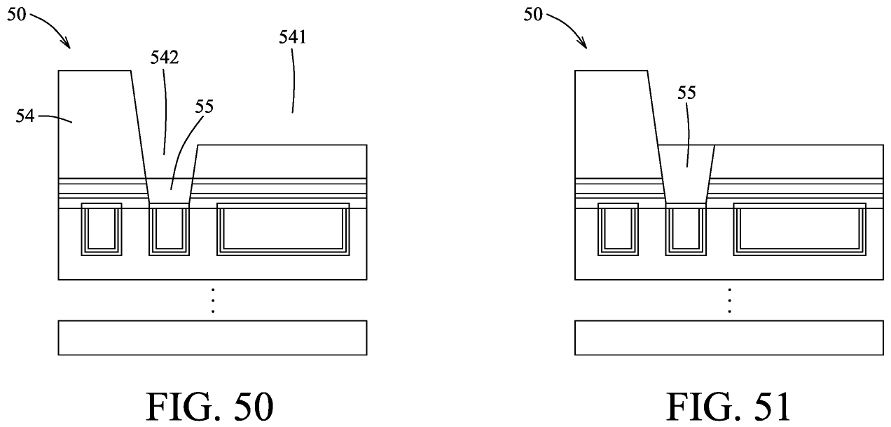

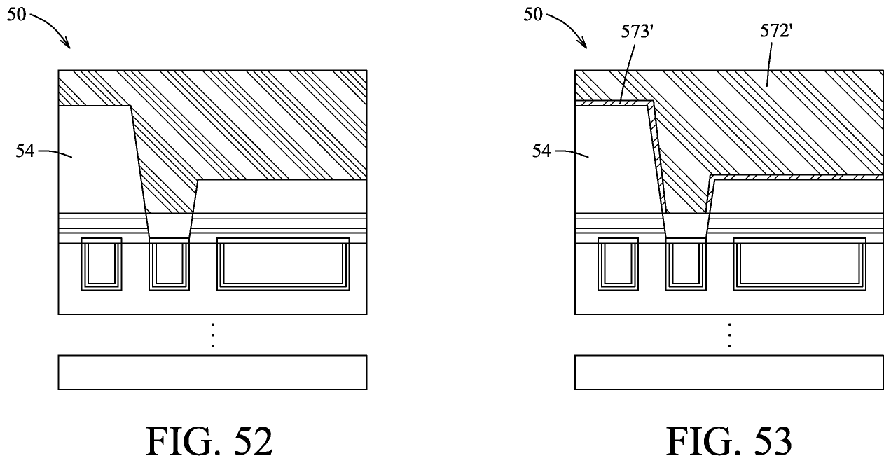

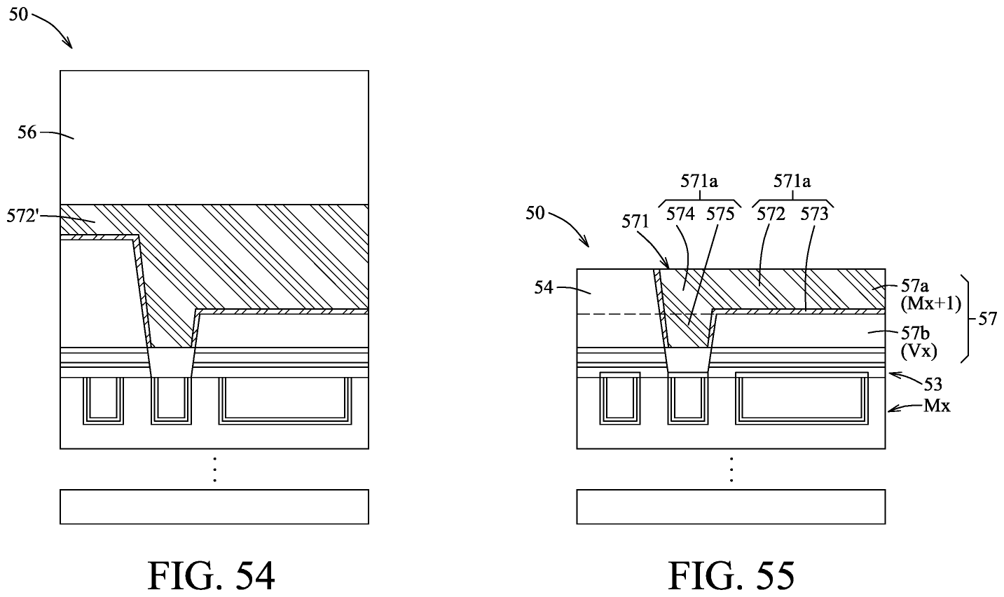

Referring to FIG. 47 and the examples illustrated in FIGS. 52 to 55, the method 500 proceeds to step 504, where an interconnect layer including an interconnect structure therein is formed. Referring to the examples illustrated in FIGS. 50, 52 and 53, a composition including the matrix and the self-forming-liner component described above with reference to FIG. 16 is filled into the via opening 542 and the trench 541, and covers the ILD layer 54. An annealing process is performed to form a bulk metal layer 572′ and a self-forming liner layer 573′. A metal layer 56 is then formed on the bulk metal layer 572′, as illustrated in FIG. 54. A planarization process (for example, but not limited to, CMP) is performed to form an interconnect layer 57. Details for the formation of the interconnect layer 57 are the same as or similar to those described above with reference to FIGS. 40 to 45.

Referring to the example illustrated in FIG. 55, the interconnect layer 57 is formed on the first metal layer (Mx), and includes the at least one etch stop layer 53 disposed on the first metal layer (Mx), the ILD layer 54 disposed on the at least one etch stop layer 53, and an interconnect structure 571 disposed in the ILD layer 54 and the at least one etch stop layer 53. The interconnect structure 571 includes an interconnect 571a extending through the ILD layer 54 and the at least one etch stop layer 53 to be electrically connected to a corresponding one of the metal lines (ML) of the first metal layer (Mx). The interconnect 571a includes a bulk metal region 572 and a single barrier/liner layer 573 disposed to separate the bulk metal region 572 from the ILD layer 54. The interconnect layer 57 includes an upper interconnect sub-layer 57a serving as a second metal layer (Mx+1) and a lower interconnect sub-layer 57b serving as a first via layer (Vx). The interconnect 571a includes an upper interconnect portion 574 serving as a metal line of the second metal layer (Mx+1), and a lower interconnect portion 575 serving as a via contact of the first via layer (Vx). In some embodiments, the upper interconnect portion 574 includes an upper portion of the bulk metal region 572 and an upper portion of the single barrier/liner layer 573. The lower interconnect portion 575 includes a lower part including the metal material, and an upper part including a lower portion of the bulk metal region 572 and a lower portion of the single barrier/liner layer 573. In some alternative embodiments, the lower interconnect portion 575 only includes the metal material without the bulk metal region 572 and the single barrier/liner layer 573.

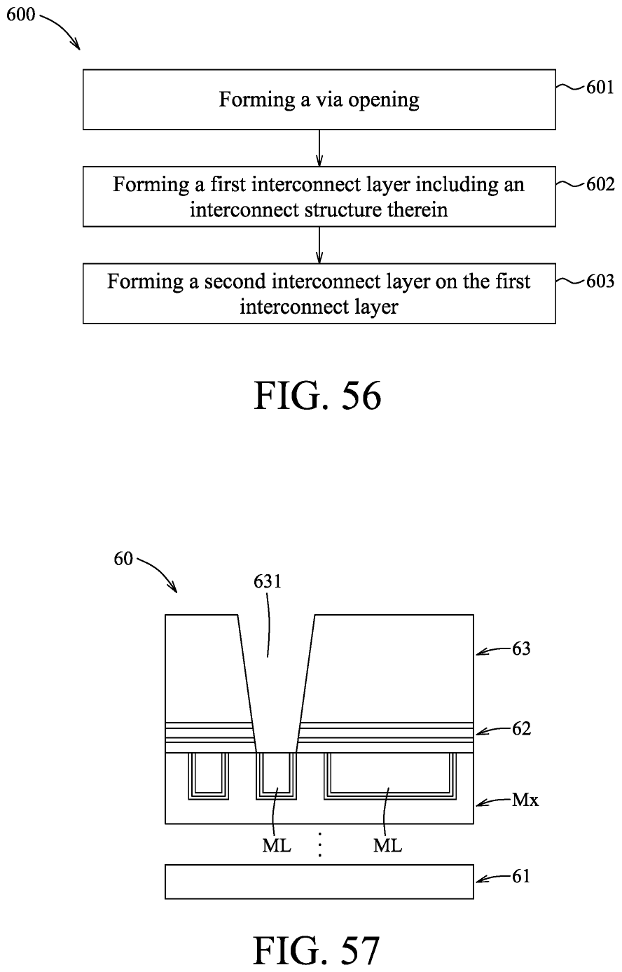

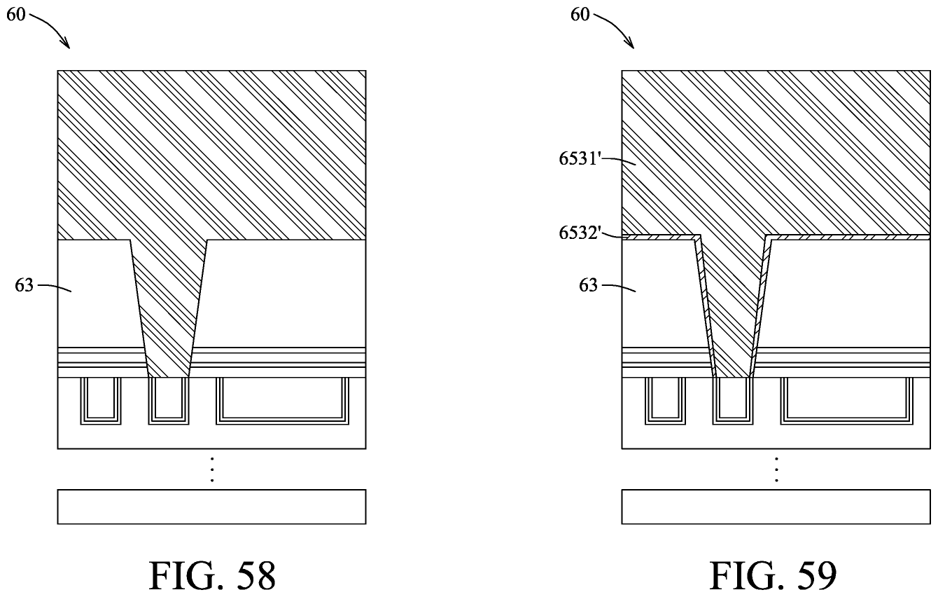

FIG. 56 illustrates a method 600 for manufacturing a semiconductor device in accordance with some embodiments. FIGS. 57 to 62 are schematic views of a semiconductor device 60 at some intermediate stages of the manufacturing method as depicted in FIG. 56 in accordance with some embodiments. Additional steps can be provided before, after or during the method 600, and some of the steps described herein may be replaced by other steps or be eliminated. Similarly, further additional features may be present in the semiconductor device 60, and/or features present may be replaced or eliminated in additional embodiments.

A single damascene process is used to form an interconnect layer with an interconnect structure. Referring to FIG. 56 and the example illustrated in FIG. 57, the method 500 begins at step 501, where a via opening is formed. At least one etch stop layer 62 is formed on a first metal layer (Mx) disposed over a substrate 61. The stack configuration, the material, and the manufacturing process of the at least one etch stop layer 62 are the same as or similar to those of the at least one etch stop layer 421 described above with reference to FIGS. 39 and 44, and the details thereof are omitted for the sake of brevity. An ILD layer 63 is then deposited on the at least one etch stop layer 62. The material and the process for forming the ILD layer 63 may be the same as or similar to those for forming the ILD layer 121 described above with reference to FIG. 2, and the details thereof are omitted for the sake of brevity. A via opening 631 is formed using an etching process (for example, but not limited to, a dry etching process, a wet etching process, or a combination thereof) through an opening pattern formed in a patterned mask layer (not shown), such that the via opening 631 penetrates through the ILD layer 63 and the at least one etch stop layer 62 to expose a corresponding one of metal lines (ML) formed in the first metal layer (Mx) therethrough.

Referring to FIG. 56 and the examples illustrated in FIGS. 57 to 60, the method 600 proceeds to step 502, where a first interconnect layer including an interconnect structure therein is formed. Referring to the examples illustrated in FIGS. 57 to 59, a composition including the matrix and the self-forming-liner component described above with reference to FIG. 16 is filled into the via opening 631, and covers the ILD layer 63. An annealing process is performed to form a bulk metal layer 6531′ and a self-forming liner layer 6532′. A planarization process (for example, but not limited to, CMP) is performed to form an interconnect layer 64. Details for the formation of the interconnect layer 64 are similar to those for the formation of the first interconnect layer 42 described above with reference to FIGS. 40 to 45.

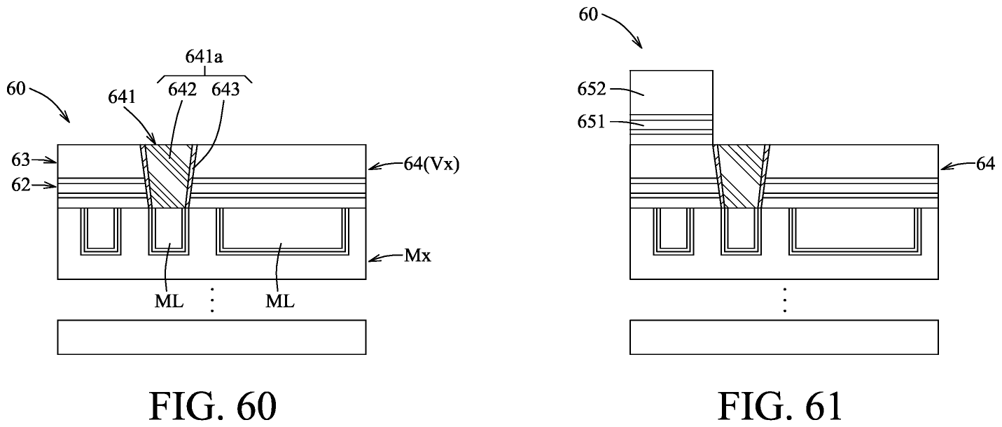

Referring to the example illustrated in FIG. 60, the interconnect layer 64 is formed on the first metal layer (Mx) and serves as a via layer (Vx). The interconnect layer 64 includes the at least one etch stop layer 62 disposed on the first metal layer (Mx), the ILD layer 63 disposed on the at least one etch stop layer 62, and an interconnect structure 641 disposed in the ILD layer 63 and the at least one etch stop layer 62. The interconnect structure 641 includes an interconnect 641a extending through the ILD layer 63 and the at least one etch stop layer 62. The interconnect 641a serves as a via contact to be electrically connected to the corresponding one of the metal lines (ML) of the first metal layer (Mx). The interconnect 641a includes a bulk metal region 642 and a single barrier/liner layer 643 disposed to separate the bulk metal region 642 from the ILD layer 63 and the at least one etch stop layer 62.

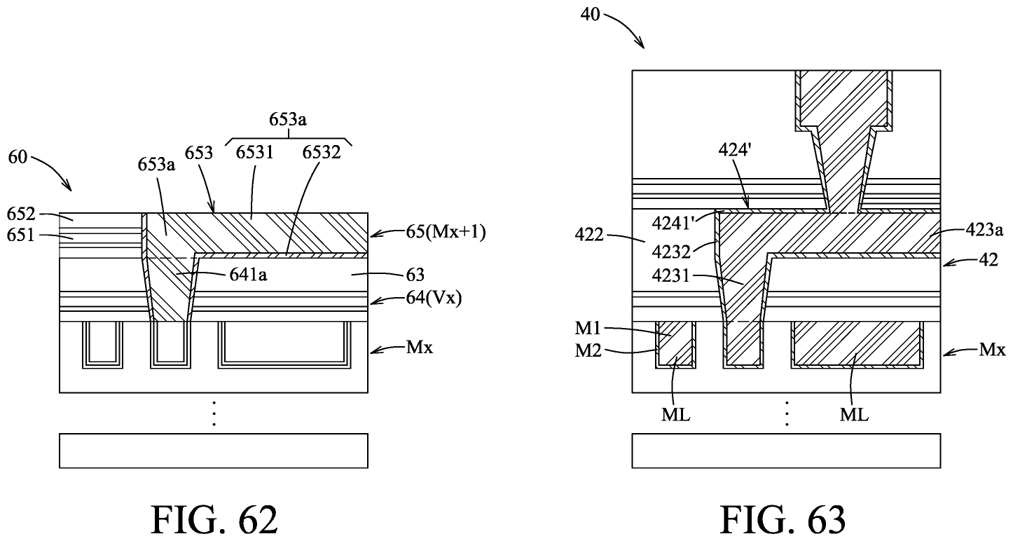

Referring to FIG. 56 and the examples illustrated in FIGS. 61 and 62, the method 600 proceeds to step 503, where a second interconnect layer is formed on the first interconnect layer. A second interconnect layer 65 is formed on the first interconnect layer 64 using a single damascene process, and severs as a metal layer (Mx+1). The materials and the processes for forming the second interconnect layer 65 are the same as or similar to those for forming the first interconnect layer 64, and the details thereof are omitted for the sake of brevity. The second interconnect layer 65 includes at least one etch stop layer 651 disposed on the first interconnect layer 64, an ILD layer 652 disposed on the at least one etch stop layer 651, and an interconnect structure 653 disposed in the ILD layer 652 and the at least one etch stop layer 651. The interconnect structure 653 includes an interconnect 653a which serves as a metal line of the metal layer (Mx+1) and which is electrically connected to the interconnect 641a of the first interconnect layer 64. The interconnect 653a includes a bulk metal region 6531 and a single barrier/liner layer 6532 disposed to separate the bulk metal region 6531 from the ILD layer 652 and the at least one etch stop layer 651.

Referring to the example illustrated in FIG. 63, the semiconductor device 40 in some alternative embodiments is similar to that illustrated in FIG. 46 except for the following differences. In the first metal layer (Mx), each of the metal lines (ML) includes a bulk metal region (M1) and a single barrier/liner layer (M2) which may be formed by the processes described above with reference to FIGS. 40 to 45. The first interconnect layer 42 includes a capping layer 424′, instead of the the capping layer 424. The capping layer 424′ includes a capping portion 4241′ disposed on the interconnect 423a. The capping portion 4241′ is formed integrally with the single barrier/liner layer 4232 by the annealing process described above with reference to FIG. 16, but the annealing process is performed after the planarization process to remove excess of the composition above the ILD layer 422.

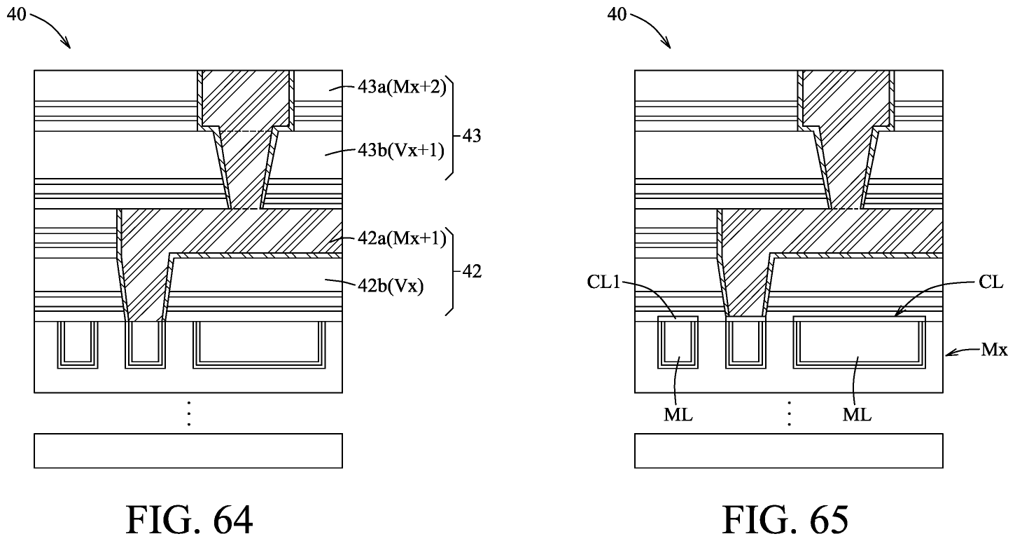

Referring to the example illustrated in FIG. 64, the semiconductor device 40 in some alternative embodiments is similar to that illustrated in FIG. 46 except for the following differences. The upper interconnect sub-layer 42a and the lower interconnect sub-layer 42b of the first interconnect layer 42 are formed separately using two single damascene processes. The upper interconnect sub-layer 43a and the lower interconnect sub-layer 43b of the second interconnect layer 43 are formed separately using two single damascene processes. The capping layer 424, which is formed in the semiconductor device 40 illustrated in FIG. 46, is not formed in the semiconductor device 40 illustrated in FIG. 64.

Referring to the example illustrated in FIG. 65, the semiconductor device 40 in some alternative embodiments is similar to that illustrated in FIG. 64 except that a capping layer (CL) is further selectively deposited on the metal lines (ML). The capping layer (CL) includes a plurality of capping portions (CL1) disposed on the metal lines (ML), respectively. The material and the process for forming the capping layer (CL) are the same as or similar to those described above for forming the capping layer 424 with reference to FIG. 45, and the details thereof are omitted for the sake of brevity.

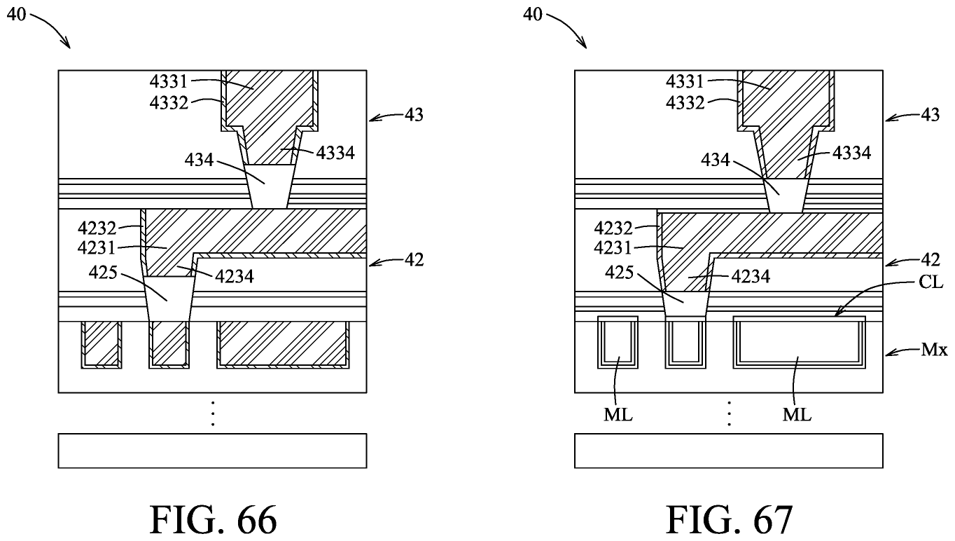

Referring to the example illustrated in FIG. 66, the semiconductor device 40 in some alternative embodiments is similar to that illustrated in FIG. 63 except for the following differences. The capping layer 424′, which is formed in the semiconductor device 40 illustrated in FIG. 63, is not formed in the semiconductor device 40 illustrated in FIG. 66. In the formation of the first interconnect layer 42, before filling the composition for forming the bulk metal region 4231 and the single barrier/liner layer 4232, a metal material 425 is selectively filled to form a via contact (i.e., the lower interconnect portion 4234) or a portion of the via contact. In the formation of the second interconnect layer 43, before filling the composition for forming the bulk metal region 4331 and the single barrier/liner layer 4332, a metal material 434 is selectively filled to form a via contact (i.e., the lower interconnect portion 4334) or a portion of the via contact.

Referring to the example illustrated in FIG. 67, the semiconductor device 40 in some alternative embodiments is similar to that illustrated in FIG. 65 except for the following differences. Each of the first and second interconnect layers 42, 43 is formed using a dual damascene process. In the formation of the first interconnect layer 42, before filling the composition for forming the bulk metal region 4231 and the single barrier/liner layer 4232, a metal material 425 is selectively filled to form a via contact (i.e., the lower interconnect portion 4234) or a portion of the via contact. In the formation of the second interconnect layer 43, before filling the composition for forming the bulk metal region 4331 and the single barrier/liner layer 4332, a metal material 434 is selectively filled to form a via contact (i.e., the lower interconnect portion 4234) or a portion of the via contact.

In a semiconductor device of the present disclosure, a single barrier/liner layer (i.e., a single layer serving as both a barrier layer and a liner layer) is formed in an interconnect (e.g., a metal line and/or a via contact) of an interconnect layer (e.g., a metal layer and/or a via layer) that is formed in a middle end of line (MEOL) process and/or a back end of line (BEOL) process. The single barrier/liner layer can have superior thermal stability and superior adhesion to a metal material (e.g., copper) serving as a bulk metal region of the interconnect, in contrast to those of a barrier layer and a liner layer separately and sequentially formed in an interconnect. The single barrier/liner layer can serve as a barrier layer to prevent the metal material from diffusion and as a liner layer to enhance gap-filling of the metal material. In addition, since the single barrier/liner layer occupy a relatively small volume of a trench and/or an opening for forming the interconnect, a remaining volume of the trench and/or the opening for filling the metal material to form the bulk metal region is increased, such that the resistance of the interconnect thus formed can be decreased. In some embodiments, the single barrier/liner layer is formed by depositing a single layer including a main component containing a liner metal and a doping component containing a barrier metal. In some embodiments, the single barrier/liner layer is formed by filling a composition including a matrix and a doping component using a deposition process, and annealing the composition to simultaneously form the bulk metal region made of the matrix and the single barrier/liner layer made of the doping component. In some embodiments, the single barrier/liner layer may be formed below a via contact so as to serve as a diffusion barrier to prevent void formation. Since the single barrier/liner layer may be formed using a deposition process in a single chamber or may be self-formed using an annealing process, the semiconductor device of the present disclosure may be manufactured with a high yield.

In accordance with some embodiments of the present disclosure, a semiconductor device includes a substrate and an interconnect layer disposed on the substrate. The interconnect layer includes a dielectric layer and an interconnect extending through the dielectric layer. The interconnect includes a bulk metal region and a single barrier/liner layer, which serves as both a barrier layer and a liner layer and which is disposed to separate the bulk metal region from the dielectric layer.

In accordance with some embodiments of the present disclosure, the single barrier/liner layer incudes a main component and a doping component which are different from each other. The main component includes cobalt, ruthenium, tantalum, or combinations thereof. The doping component includes tantalum, zinc, manganese, zirconium, titanium, hafnium, niobium, vanadium, chromium, scandium, yttrium, silicon, tungsten, molybdenum, aluminum, or combinations thereof.

In accordance with some embodiments of the present disclosure, the single barrier/liner layer includes a self-forming-liner component including a metal, a silicide of the metal, or an oxide of the metal which possesses diffusion barrier property.

In accordance with some embodiments of the present disclosure, the metal includes aluminum, manganese, titanium, zirconium, hafnium, niobium, tantalum, molybdenum, tungsten, zinc, vanadium, chromium, scandium, iron, yttrium, germanium, gallium, indium, tin, or combinations thereof.

In accordance with some embodiments of the present disclosure, the single barrier/liner layer has a thickness ranging from 0.1 nm to 10 nm.

In accordance with some embodiments of the present disclosure, the interconnect layer further includes a capping region disposed on the interconnect. The capping region is formed integrally with the single barrier/liner layer of the interconnect and includes the self-forming liner component.

In accordance with some embodiments of the present disclosure, the interconnect includes an upper interconnect portion and a lower interconnect portion. The upper interconnect portion includes an upper portion of the bulk metal region and an upper portion of the single barrier/liner layer. The lower interconnect portion includes a lower part and an upper part. The lower part includes a metal material including copper, silver, gold, aluminum, nickel, cobalt, ruthenium, iridium, platinum, palladium, osmium, tungsten, molybdenum, tantalum, or combinations thereof. The upper part includes a lower portion of the bulk metal region and a lower portion of the single barrier/liner layer.

In accordance with some embodiments of the present disclosure, a method for manufacturing a semiconductor device includes: forming a dielectric layer on a substrate; etching the dielectric layer to form an opening extending through the dielectric layer; conformally depositing a single layer including a main component and a doping component on the dielectric layer, the main component including a liner metal, the doping component including a barrier metal; filling a metal material into the opening; and removing excess of the single layer and excess of the metal material over the dielectric layer to form an interconnect, which includes a bulk metal region and a single barrier/liner layer disposed to separate the bulk metal region from the dielectric layer, the bulk metal region including the metal material, the single barrier/liner layer including the liner metal and the barrier metal.

In accordance with some embodiments of the present disclosure, the liner metal includes cobalt, ruthenium, tantalum, or combinations thereof, and the barrier metal includes tantalum, zinc, manganese, zirconium, titanium, hafnium, niobium, vanadium, chromium, scandium, yttrium, silicon, tungsten, molybdenum, aluminum, or combinations thereof. The liner metal and the barrier metal are different from each other.

In accordance with some embodiments of the present disclosure, the single layer is conformally deposited on the dielectric layer at a temperature ranging from 25° C. to 400° C.

In accordance with some embodiments of the present disclosure, the method for manufacturing a semiconductor device further includes, prior to filling the metal material into the opening, depositing a further single barrier/liner layer on the single barrier/liner layer, such that the further single barrier/liner layer and the single barrier/liner layer are combined with each other to be configured as an integrated layer.

In accordance with some embodiments of the present disclosure, the method for manufacturing a semiconductor device further includes, prior to filling the metal material into the opening, doping a composition including the main component and the doping component into the single barrier/liner layer.

In accordance with some embodiments of the present disclosure, a method for manufacturing a semiconductor device includes: forming a dielectric layer on a substrate; etching the dielectric layer to form an opening extending through the dielectric layer; filling a composition including a matrix and a doping component into the opening by a deposition process, the matrix including a metal material, the doping component including a self-forming-liner component possessing diffusion barrier property; and annealing the composition so as to form an interconnect penetrating the dielectric layer, the interconnect including a bulk metal region and a single barrier/liner layer disposed to separate the bulk metal region from the dielectric layer, the bulk metal region including the matrix, the single barrier/liner layer including the doping component.

In accordance with some embodiments of the present disclosure, the self-forming-liner component includes a metal, a silicide of the metal, or an oxide of the metal. The metal includes aluminum, manganese, titanium, zirconium, hafnium, niobium, tantalum, molybdenum, tungsten, zinc, vanadium, chromium, scandium, iron, yttrium, germanium, gallium, indium, tin, or combinations thereof.

In accordance with some embodiments of the present disclosure, a bulk metal layer including the matrix and a self-forming liner layer including the doping component are formed by annealing the composition. The self-forming liner layer is conformally formed on the dielectric layer to separate the bulk metal layer from the dielectric layer. The method for manufacturing a semiconductor device further includes removing excess of the bulk metal layer and excess of the self-forming liner layer over the dielectric layer to form the interconnect.

In accordance with some embodiments of the present disclosure, the method for manufacturing a semiconductor device further includes, prior to annealing the composition, removing excess of the composition over the dielectric layer such that a capping layer is formed integrally with the single barrier/liner layer of the interconnect by annealing the composition and is disposed on the interconnect.

In accordance with some embodiments of the present disclosure, the composition is annealed at a temperature ranging from 100° C. to 1400° C.

In accordance with some embodiments of the present disclosure, the composition is annealed after the deposition process for filling the composition into the opening is completed.

In accordance with some embodiments of the present disclosure, annealing of the composition is performed simultaneously with filling of the composition by performing the deposition process at a temperature ranging from 100° C. to 1400° C.

In accordance with some embodiments of the present disclosure, the method for manufacturing a semiconductor device further includes, prior to filling the composition, pre-filling the metal material into the opening to form a lower portion of the interconnect.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a substrate; and
an interconnect layer disposed on the substrate and including:
a dielectric layer, and
an interconnect extending through the dielectric layer, and including a bulk metal region and a single barrier/liner layer, which serves as both a barrier layer and a liner layer and which is disposed to separate the bulk metal region from the dielectric layer.

2. The semiconductor device according to claim 1, wherein the single barrier/liner layer includes:
a main component including cobalt, ruthenium, tantalum, or combinations thereof; and
a doping component including tantalum, zinc, manganese, zirconium, titanium, hafnium, niobium, vanadium, chromium, scandium, yttrium, silicon, tungsten, molybdenum, aluminum, or combinations thereof,
the main component and the doping component being different from each other.

3. The semiconductor device according to claim 1, wherein the single barrier/liner layer includes a self-forming-liner component including a metal, a silicide of the metal, or an oxide of the metal which possesses diffusion barrier property.

4. The semiconductor device according to claim 3, wherein the metal includes aluminum, manganese, titanium, zirconium, hafnium, niobium, tantalum, molybdenum, tungsten, zinc, vanadium, chromium, scandium, iron, yttrium, germanium, gallium, indium, tin, or combinations thereof.

5. The semiconductor device according to claim 1, wherein the single barrier/liner layer has a thickness ranging from 0.1 nm to 10 nm.

6. The semiconductor device according to claim 3, wherein the interconnect layer further includes a capping region disposed on the interconnect, the capping region being formed integrally with the single barrier/liner layer of the interconnect and including the self-forming liner component.

7. The semiconductor device according to claim 1, wherein the interconnect includes:
an upper interconnect portion including an upper portion of the bulk metal region and an upper portion of the single barrier/liner layer; and
a lower interconnect portion including:
a lower part including a metal material which includes copper, silver, gold, aluminum, nickel, cobalt, ruthenium, iridium, platinum, palladium, osmium, tungsten, molybdenum, tantalum, or combinations thereof, and
an upper part including a lower portion of the bulk metal region and a lower portion of the single barrier/liner layer.

8. A method for manufacturing a semiconductor device, comprising:
forming a dielectric layer on a substrate;
etching the dielectric layer to form an opening extending through the dielectric layer;
conformally depositing a single layer including a main component and a doping component on the dielectric layer, the main component including a liner metal, the doping component including a barrier metal;
filling a metal material into the opening; and
removing excess of the single layer and excess of the metal material over the dielectric layer to form an interconnect, which includes a bulk metal region and a single barrier/liner layer disposed to separate the bulk metal region from the dielectric layer, the bulk metal region including the metal material, the single barrier/liner layer including the liner metal and the barrier metal.

9. The method according to claim 8, wherein the liner metal includes cobalt, ruthenium, tantalum, or combinations thereof, the barrier metal includes tantalum, zinc, manganese, zirconium, titanium, hafnium, niobium, vanadium, chromium, scandium, yttrium, silicon, tungsten, molybdenum, aluminum, or combinations thereof, and the liner metal and the barrier metal are different from each other.

10. The method according to claim 8, wherein the single layer is conformally deposited on the dielectric layer at a temperature ranging from 25° C. to 400° C.

11. The method according to claim 8, further comprising, prior to filling the metal material into the opening, depositing a further single barrier/liner layer on the single barrier/liner layer, such that the further single barrier/liner layer and the single barrier/liner layer are combined with each other to be configured as an integrated layer.

12. The method according to claim 8, further comprising, prior to filling the metal material into the opening, doping a composition including the main component and the doping component into the single barrier/liner layer.

13. A method for manufacturing a semiconductor device, comprising:
forming a dielectric layer on a substrate;
etching the dielectric layer to form an opening extending through the dielectric layer;
filling a composition including a matrix and a doping component into the opening by a deposition process, the matrix including a metal material, the doping component including a self-forming-liner component possessing diffusion barrier property; and
annealing the composition so as to form an interconnect penetrating the dielectric layer, the interconnect including a bulk metal region and a single barrier/liner layer disposed to separate the bulk metal region from the dielectric layer, the bulk metal region including the matrix, the single barrier/liner layer including the doping component.

14. The method according to claim 13, wherein the self-forming-liner component includes a metal, a silicide of the metal, or an oxide of the metal, the metal including aluminum, manganese, titanium, zirconium, hafnium, niobium, tantalum, molybdenum, tungsten, zinc, vanadium, chromium, scandium, iron, yttrium, germanium, gallium, indium, tin, or combinations thereof.

15. The method according to claim 13, wherein a bulk metal layer including the matrix and a self-forming liner layer including the doping component are formed by annealing the composition, the self-forming liner layer being conformally formed on the dielectric layer to separate the bulk metal layer from the dielectric layer, the method further including removing excess of the bulk metal layer and excess of the self-forming liner layer over the dielectric layer to form the interconnect.

16. The method according to claim 13, further comprising, prior to annealing the composition, removing excess of the composition over the dielectric layer, such that a capping layer is formed integrally with the single barrier/liner layer of the interconnect by annealing the composition and is disposed on the interconnect.

17. The method according to claim 13, wherein the composition is annealed at a temperature ranging from 100° C. to 1400° C.

18. The method according to claim 17, wherein the composition is annealed after the deposition process for filling the composition into the opening is completed.

19. The method according to claim 17, wherein annealing of the composition is performed simultaneously with filling of the composition by performing the deposition process at a temperature ranging from 100° C. to 1400° C.

20. The method according to claim 13, further comprising, prior to filling the composition, pre-filling the metal material into the opening to form a lower portion of the interconnect.
